(19) United States
(12) Patent Application Publication
(10) Pub. No.: US 2026/0106623 A1
(43) Pub. Date: Apr. 16, 2026

(54) ANALOG-TO-DIGITAL CONVERTER FOR SUPPORTING ANALOG COMPUTATION

(71) Applicant: Fractile Ltd, Newbury (GB)

(72) Inventor: Anthony Ian STANSFIELD, Newbury (GB)

(21) Appl. No.: 19/354,735

(22) Filed: Oct. 9, 2025

(30) Foreign Application Priority Data
Oct. 10, 2024 (GB) 2414920.5

(51) Int. Cl. H03M 1/08; H03M 1/12

(52) U.S. Cl. CPC H03M 1/0854; H03M 1/12

(57) ABSTRACT

There is provided a method of transforming a sequence of analog inputs into a quantized digital outputs. The method comprises: receiving in an analog processing domain a first analog input of the sequence, and generating in the analog processing domain, based on the first analog input, a first analog output. The method further comprises: quantizing the first analog output, resulting in: (i) a first quantized digital output, and (ii) a first analog residual error, and scaling in the analog processing domain the first analog residual error, resulting in a first analog scaled residual error. The method further comprises: receiving in the analog processing domain a second analog input of the input sequence, generating in the analog processing domain, based on the second analog input and the first scaled analog residual error, a second analog output, and quantizing the second analog output, resulting in a second quantized digital output.

### TECHNICAL FIELD

The present disclosure pertains to an analog-to-digital converter for supporting analog computation.

### BACKGROUND

In the field of artificial intelligence (AI), recent years and months have seen rapid advances in so-called large machine learning (ML) models, such as large language models (LLMs) and other foundational models. Such models typically take the form of artificial neural networks (neural networks or neural nets for short) having billions of parameters (weights) or more, requiring vast investments in computational resources. However, advances in the technology have relied on very similar hardware. Existing chips and highly developed tools and libraries are well-optimised for training large language models (LLMs), but they are unsuited to inference, which is the process of running live data (input tokens) through a specific model with learned parameters, to produce results (in LLMs, a series of output tokens). A token may take the form of a vector of numerical values.

As a consequence, AI models are very expensive to provision and run at scale. Issues such as time taken on conventional hardware to move model parameters from memory to processors mean that very expensive hardware is often used at a small fraction of its theoretical capability.

Moreover, AI performance is inhibited, as ever faster compute cannot make up for the performance lag caused in inference by moving model weights from memory to the processor units, limiting real-time performance and user experience.

Potential AI performance in the future is also restricted. Continual advancement of conventional computing is limited by the heat generated by these chips. There is a limit to how fast silicon chips can be cooled, and this has become a new constraint on continuing to scale conventional digital processors (the end of Dennard Scaling). With enough data, bigger AI models are predictably better, but without breakthroughs in compute systems, it will not be possible to continue to scale AI models to be orders of magnitude larger with sufficiently low latency (time per output token, for instance) to be usable.

Moreover, with AI model developers all building on similar infrastructure and the balance of its use tilting heavily to inference, without novel hardware the opportunity to create long-term differentiation and competitive advantage from faster, cheaper and higher quality token generation in inference will be limited.

There are broadly two development paths available when building improved hardware for AI inference. The first is specialisation: honing in on very specific workloads and building chips that are uniquely suited to those specific requirements. Because model architectures evolve rapidly in the world of AI, while designing, verifying, fabricating and testing chips takes considerable time, companies pursuing this approach face the problem of shooting for a moving target whose exact direction is uncertain.

The second path is to change the way that computational operations themselves are performed, create different chips from novel building blocks, and build scalable systems on top of these.

### SUMMARY

Analog computing is a promising approach that addresses several limitations of traditional digital computing. Unlike digital systems that rely on binary representations, analog computing processes more aligned with certain tasks in AI, and can offer significant advantages in terms of energy efficiency, speed, and reduced data bottlenecks. One issue addressed herein relates to analog-to-digital conversion. In an analog computing context, certain computations can be performed highly efficiently in analog, but in practice the results back will likely need to be transformed back to the digital processing domain. One aim herein is to implement an analog-to-digital (ADC) converter in circuitry with reduced size and power consumption, and which can operate at increased speed. This can be achieved by reducing the precision of the ADC. This reduction in ADC resolution would normally come at the cost of reduced resolution in the digital output. However, that tradeoff is avoided with the present ADC architecture, which retains residual quantization errors in the analog processing domain. As a sequence of analog inputs is processed in serial fashion over multiple computation cycles, the analog errors are propagated across the sequence to future cycle(s).

An important application of the ADC architecture is analog computing. In some such applications, the analog inputs are weighted inputs, obtained by multiplying an incoming unweighted input (activation) with a stored weight in the analog processing domain. The weighted analog input may be one of multiple such inputs, which are summed in the analog processing domain (e.g. to implement vector-vector or vector-matrix multiplication), before the resulting output is transformed to a digital format. However, the present ADC architecture can be applied more generally in other contexts to transform a sequence of analog inputs to quantized digital outputs.

According to a first aspect herein, a method of transforming a sequence of analog inputs into a quantized digital outputs comprises: receiving in an analog processing domain a first analog input of the sequence; generating in the analog processing domain, based on the first analog input, a first analog output; quantizing the first analog output, resulting in: (i) a first quantized digital output, and (ii) a first analog residual error; scaling in the analog processing domain the first analog residual error, resulting in a first analog scaled residual error; receiving in the analog processing domain a second analog input of the input sequence; generating in the analog processing domain, based on the second analog input and the first scaled analog residual error, a second analog output; and quantizing the second analog output, resulting in a second quantized digital output.

According to a second aspect herein, there is provided an analog computer comprising circuitry configured to implement the method of the first aspect.

In some examples, the analog computer comprises: first logic in the form of fixed-logic circuitry configured to implement the steps performed in the analog processing domain, and second logic configured to implement any steps performed in the digital processing domain, the second circuitry comprising fixed-logic circuitry, programmable circuitry, a programmable processor or any combination thereof.

According to a third aspect herein, a device comprises: an output line; an input line coupled to the output line; an analog data store coupled to the output line; an analog-to-digital converter (ADC) configured to quantize an earlier analog output value on the output line, the earlier analog output value dependent on an earlier analog input value received on the input line, resulting in an earlier quantized digital output, the ADC coupled to the analog data store so as to cause an analog residual error arising from quantizing the earlier analog output value to be stored in the analog data store; and an error scaling circuit configured to scale the analog residual error, thereby causing a scaled analog residual error to be stored in the analog data store, wherein the ADC is configured to quantize a later analog output value on the output line, resulting in a later quantized digital output, the later analog output value dependent on the scaled analog residual error and a later analog input value received on the input line.

In some examples, the input line and analog data store are coupled to the output line via respective capacitors, wherein the earlier analog output value has the form of an earlier output voltage change on the output line, and the later analog output value has the form of a later output voltage change on the output line.

In some examples, the analog data store is coupled to a second portion of the output line via a feedback capacitor, wherein the error scaling circuit comprises a pass gate controllable to decouple the analog data store from a first portion of the output line, thereby generating the scaled analog residual error.

In some examples, the first portion of the output line includes an output capacitor.

In some examples, the input line is one of multiple input lines coupled to the output lines via respective capacitors, the earlier analog output value dependent on multiple earlier analog input values received on the multiple input lines, and the later analog output value dependent on multiple later analog input values received on the multiple input lines.

In some examples, the earlier output voltage change depends on a weighted sum of the multiple earlier input values, and the later output voltage change depends on a weighted sum of the multiple later input values.

In some examples, the device further comprises a multiplication circuit coupled to each input line and configured to multiply the input value on that input line with a stored weight.

In some examples, the device further comprises an accumulator configured to accumulate the earlier quantized digital output and the later quantized digital output.

In some examples, the ADC comprises: a comparator having an input connected to the output line and an output configured to output the quantized digital outputs, and a pre-charge loop connecting the output of the comparator to the input of the comparator and a pass gate controllable to activate the pre-charge loop.

In some examples, the comparator is an inverter.

In some examples, the analog data store comprises a first storage line configured to store a first voltage and a second signal line configured to store a second voltage, the device configured to generate a feedback voltage change on the output line by switching an output of the analog data store between the first storage line and the second storage line.

In some examples, the device further comprises a second output line; a second input line coupled to the second output line; a second analog data store coupled to the second output line; a second analog-to-digital converter configured to quantize a second earlier analog output value on the second output line, the second earlier analog output value dependent on a second earlier input value received on the second input line, resulting in a second earlier quantized digital output, the second ADC coupled to the second analog data store so as to cause a second analog residual error arising from quantizing the second earlier analog output value to be stored in the second analog data store; and a second error scaling circuit configured to scale the second analog residual error stored in the second analog data store, thereby causing a second scaled analog residual error to be stored in the second analog data store, wherein the second ADC is configured to quantize a second later analog output value on the second output line, resulting in a second later quantized digital output, the second later analog output value dependent on the second scaled analog residual error and a second later input value received on the second input line.

In some examples, the accumulator is configured to accumulate earlier quantized digital output, the later quantized digital output, the second earlier quantized digital output, and the second later quantized digital output.

Another aspect herein relates to an analog in-memory computing architecture that enables a multiplication between an analog input and a digital stored weight to be implemented highly efficiently in analog.

According to one such aspect, an in-memory compute cell for storing a digital weight and performing an in-memory signed multiplication between an incoming analog input and the stored digital weight comprises: digital cell memory configured to store a digital weight; a first activation input configured to receive an analog input; a second activation input configured to receive an additive inverse of the analog input; a cell output; a first pass gate having a signal input coupled to the first activation input, a control input coupled to the digital cell memory, and a signal output coupled to the cell output; and a second pass gate having a signal input coupled to the second activation input, a control input coupled to the digital cell memory, and a signal output coupled to the cell output, the in-memory compute cell configured so that: when a positive digital weight is stored in the digital cell memory, the first activation input is coupled via the first pass gate to the cell output and the second activation input is decoupled from the cell output, thereby generating at the cell output, based on the analog input received at the first activation input, a first analog signed multiplication output, and when a negative digital weight is stored in the digital cell memory, the second activation input is coupled via the second pass gate to the cell output and the first activation input is decoupled from the cell output, thereby generating at the cell output, based on the additive inverse of the analog input received at the second activation input, a second analog signed multiplication output.

In some examples, when a digital weight of zero is stored in the digital cell memory, neither of the first or second pass gate is activated, enabling multiplication by zero.

In-memory processor design, also known as Processing-in-Memory (PIM), integrates processing capabilities directly within memory. This contrasts with a more conventional approach, in which data is repeatedly moved between a memory and a processor (typically being copied from the memory to one or more registers of the processors, and vice versa). In the present context, the weight is stored and applied directly in memory.

The architecture supports a “weight-stationary” operation with the weight retained in the closely coupled memory as a stream of analog activations is received and multiplied with the same weight. Each activation is represented as an analog input pair, and in such use cases, the weight is stored statically in the cell memory and applied directly to incoming activations (triggering the appropriate selection).

A key mathematical operation underpinning AI models such as foundational models is vector-matrix multiplication, typically involving multiplication of incoming vectors with large matrices of weights (typically containing hundreds, thousands or more weights in a given model layer). Vector-matric multiplication can be implemented using multiple in-memory compute cells each configured as set out above, with their results summed in the analog processing domain (e.g. based on capacitive summing).

According to a fourth aspect herein, there is provided a processor, chip or die embodying the device of the third aspect.

According to a fifth aspect herein, there is provided a device comprising: an operational amplifier with a first non-inverting input, a second non-inverting input, a first inverting input, and a second inverting input; a feedback circuit connected between an output of the operational amplifier and the first and the second inverting inputs, the feedback circuit comprising: a first sub-circuit between the output and the first inverting input, the first sub-circuit comprising a first capacitor and a second capacitor connected in series, and a first pass gate connected in parallel with the first capacitor; and a second sub-circuit between the output and the second inverting input, the second sub-circuit comprising a third capacitor and a fourth capacitor connected in series, and a second pass gate connected in parallel with the third capacitor; and control circuitry configured to: operate select signals which couple one of the first and the second non-inverting inputs to the operational amplifier and couple one of the first and the second inverting inputs to the operational amplifier, and operate the first and the second pass gates in a plurality of phases so that the first and second sub-circuits store voltages related to two input voltages that are input to at least one of the first and the second non-inverting inputs, wherein the device is configured to generate, at the output, a voltage proportional to a difference between the two input voltages with an input offset of the operational amplifier substantially cancelled out.

In some examples, the first non-inverting input is configured to receive a bit-line voltage and the second non-inverting input is configured to receive a reference voltage.

In some examples, a first select signal of the select signals is arranged to couple the first non-inverting input to the operational amplifier and a second select signal of the select signals is arranged to couple the second non-inverting input to the operational amplifier, and wherein only one of the first select signal and the second select signal is active at a time instance, so that only one of the non-inverting inputs is coupled to the operational amplifier at that time instance.

In some examples, a third select signal of the select signals is arranged to couple the first inverting input to the operational amplifier and a fourth select signal of the select signals is arranged to couple the second inverting input to the operational amplifier, and wherein only one of the third select signal and the fourth select signal is active at a time instance, so that only one of the inverting inputs is coupled to the operational amplifier at that time instance.

In some examples, the control circuitry is configured to: close the first pass gate, couple the first non-inverting input to the operational amplifier, and couple the first inverting input to the operational amplifier, such that the second capacitor stores a first voltage corresponding to a first input voltage of the two input voltages modified by the input offset of the operational amplifier.

In some examples, the control circuitry is further configured to: close the second pass gate and open the first pass gate, maintain coupling of the first non-inverting input to the operational amplifier, and to couple the second inverting input to the operational amplifier, such that the fourth capacitor stores a second voltage corresponding to a second input voltage of the two input voltages modified by the input offset of the operational amplifier and the voltage stored on the second capacitor is shifted by the change in voltage at the output of the operational amplifier.

In some examples, the control circuitry is further configured to: open the first pass gate and the second pass gate, maintain coupling of the second inverting input to the operational amplifier, couple the second non-inverting input to the operational amplifier, thereby causing the operational amplifier to shift its output so that the voltage at the second inverting input cancels the input offset.

In some examples, the control circuitry is further configured to: maintain the coupling of the second non-inverting input to the operational amplifier, couple the first inverting input to the operational amplifier, and maintain the pass gates open, thereby causing the operational amplifier to shift its output so that the voltage at the first inverting input cancels the input offset, wherein the operational amplifier outputs the voltage proportional to the difference between the first and second input voltages with the input offset of the operational amplifier substantially cancelled out.

In some examples, a first input voltage of the two input voltages is coupled to the first non-inverting input, and a second input voltage of the two input voltages is coupled to the second non-inverting input, at different time instances, wherein the voltage proportional to the difference between the two input voltages output by the device is a voltage proportional to a difference between voltages on the first non-inverting input and the second non-inverting input.

In some examples, the first and the second capacitors are arranged as a capacitive voltage divider in the first sub-circuit, and wherein the third and the fourth capacitors are arranged as a further capacitive voltage divider in the second sub-circuit.

In some examples, at least one of: the first capacitor and the third capacitor have substantially equal capacitance values, or the second capacitor and the fourth capacitor have substantially equal capacitance values.

In some examples, a ratio of the second and fourth capacitors to the first and third capacitors set the gain of the operational amplifier.

In some examples, the operational amplifier is integrated together with the feedback circuit and the control circuitry on a common semiconductor substrate.

In some examples, the device is configured for use in artificial-intelligence or machine-learning computations requiring determination of differences between stored analog values.

### BRIEF DESCRIPTION OF FIGURES

Particular embodiments will now be described, by way of example only, with reference to the following schematic figures, in which:

FIG. 1A shows an analog computing architecture;

FIG. 1B shows an example of a low-precision quantization scheme;

FIG. 1C shows an example of a quantized input vector and weight matrix;

FIG. 1D shows an example number format used to represent quantized values;

FIG. 1E shows an example of a processing flow based on low precision analog-to-digital conversion with propagation of residual analog errors;

FIG. 2A shows a high level block diagram of a dual-bit memory cell

FIG. 2B shows a high-level circuit diagram of an in-memory compute cell for storing a digital weight and performing an in-memory signed multiplication between an incoming analog input and the stored digital weight;

FIG. 2C shows examples of signed multiplication using the in-memory compute cell of FIG. 2B;

FIG. 2D shows an example SRAM implementation of an in-memory compute cell;

FIG. 2E shows one example of a digital-to-analog input mechanism;

FIG. 2F shows a second example of a digital-to-analog input mechanism;

FIG. 3A shows a matrix multiplication between an input vector and a weight matrix;

FIG. 3B shows a matrix multiplication between an input vector and a weight matrix represented in a chosen number format;

FIG. 3C shows a schematic block diagram of an analog vector-matrix multiplication architecture;

FIG. 4A shows an example of a high-precision ADC and accumulation architecture;

FIG. 4B shows an example processing flow for high-precision ADC and accumulation;

FIG. 5A shows an example of a low-precision ADC and accumulation architecture with residual analog error propagation;

FIG. 5B shows an example processing flow for low-precision ADC and accumulation with residual analog error propagation;

FIG. 6A shows a flow chart for an example analog-to-digital conversion method;

FIG. 6B shows a schematic circuit block diagram of a device incorporating an analog vector-matrix computation architecture supported by low-precision ADC with feedback of residual analog errors;

FIG. 6C shows further details of the architecture of FIG. 6B in one embodiment;

FIG. 6D shows example mechanisms of generating a threshold voltage change;

FIG. 6E shows a schematic circuit diagram of an analog data store in one implementation;

FIG. 7A shows further details of an accumulator for accumulating digital outputs across columns of a weight matrix;

FIG. 7B shows a further example of ADC with residual analog error feedback applied to convert vector-matrix multiplication results from analog to digital;

FIG. 8 shows various example mechanisms for generating voltage changes;

FIG. 9 shows an alternative in-memory compute cell architecture;

FIGS. 10A-D shows examples of capacitive summing circuit elements;

FIGS. 11A-B shows examples of bit control circuitry.

FIG. 12 shows a schematic circuit diagram for offset cancellation in an operational amplifier.

### DETAILED DESCRIPTION

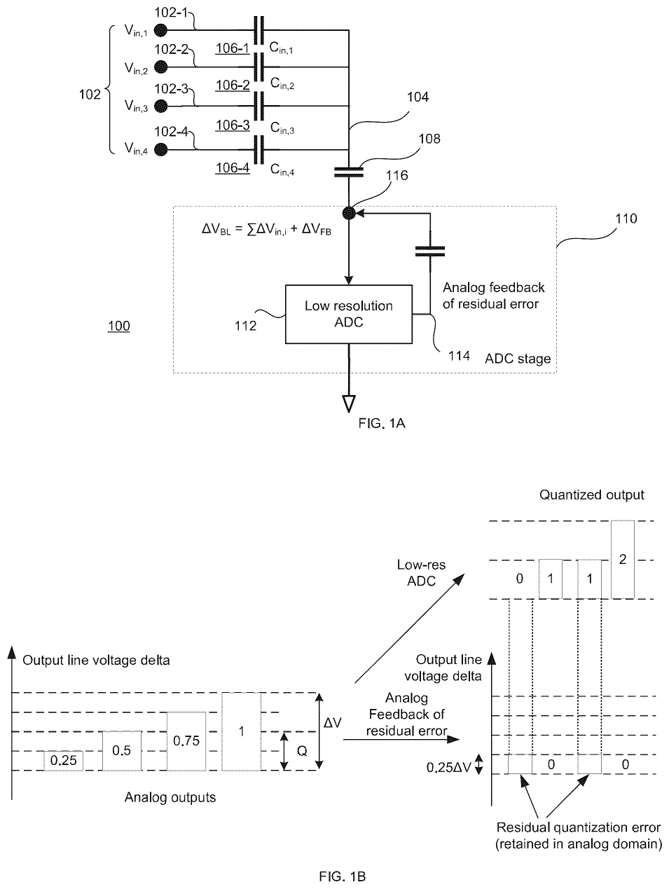

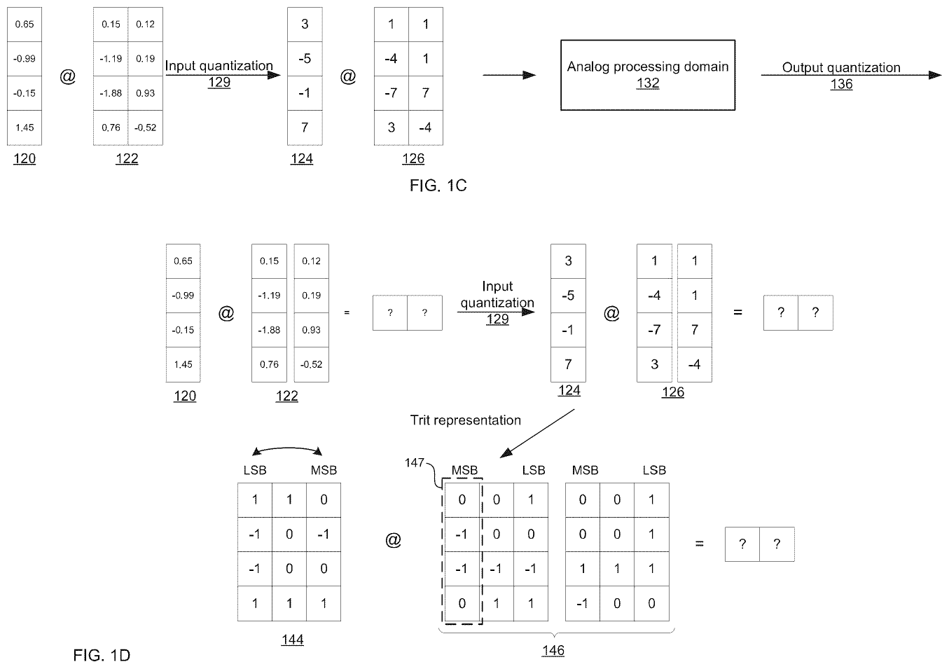

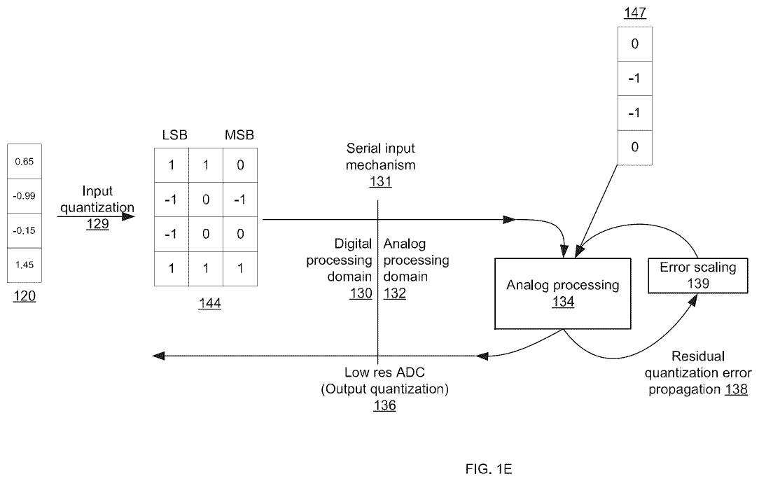

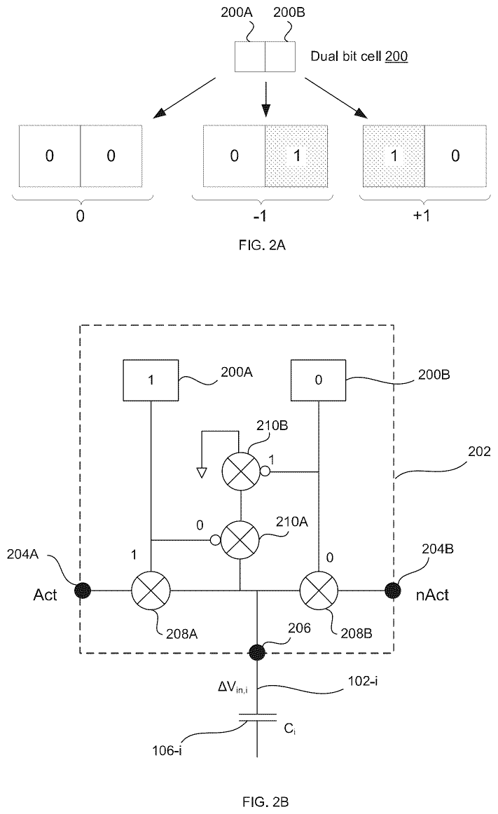

FIG. 1A shows a schematic circuit diagram of an analog computing architecture 100 in one example embodiment. The analog computing architecture 100 supports certain computations in an analog processing domain (denoted by reference sign 132 in later figures). The analog computing architecture 100 is shown to comprise multiple input lines 102 (individually labelled 102-1, . . . , 102-4), which are coupled in parallel with each other to an output line 104 via respective input capacitors 106-1, . . . , 106-4, having capacitances C_{in,1}, . . . , C_{in,4} respectively. In this arrangement, each input line 102-i is capacitively coupled to the output line 104, with its input capacitor 106-i acting as a coupling capacitor. Four input lines 102 are shown, however the described architecture can be implemented with any number of input lines N. The following examples have N=4 but the description applies equally to other values of N. The output line 104 includes an output capacitor 108. The output line 104 is sometime referred to as a bitline in the examples below, or more generally as a “digitline”. The rationale for this terminology is explained below.

Analog inputs are received on the input lines 104. An analog output computed from the analog inputs is generated on the output line 104.

An important characteristic of the analog computing architecture 100 is that values are represented as voltage changes (voltage deltas) in a given computation cycle. For example, in certain implementations, positive values are represented as positive voltage changes (rising edges), negative values are represented as negative voltage changes (falling edges) and a value of zero is represented as no change (no edge). The magnitude of the voltage change represents the magnitude of the value, e.g. in the examples below, a value of +1 is represented as a positive voltage data of a certain magnitude and a value of +2 is represented as a positive voltage delta of twice that magnitude. The voltage change ΔV_{in,i} represents an input value on the ith input line.

Voltages on the input lines 102-1, . . . , 102-4 are denoted V_{in,1}, . . . , V_{in,4} respectively, and an input value on the ith input line 102-i is represented as a voltage change on the ith input line, denoted ΔV_{in,i}. Voltage on the output line is denoted V_{PB} and the output value computed from the input values is represented by a voltage change on the output line 108 ΔV_{PB}.

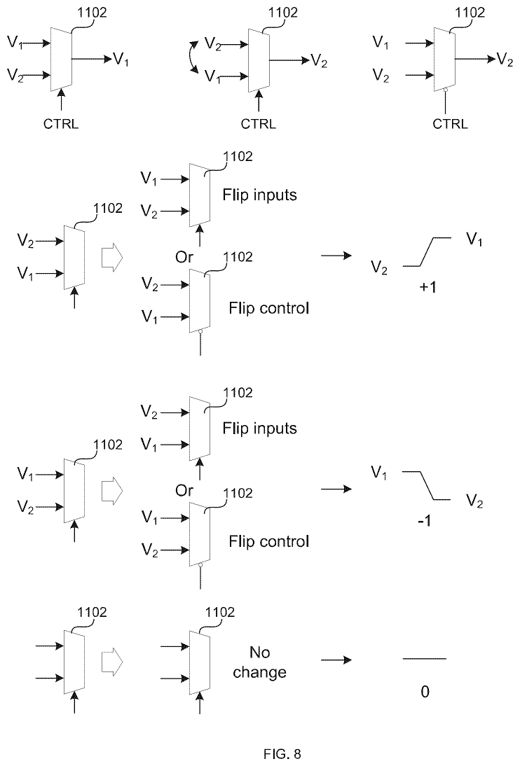

FIG. 8 shows a mechanism for generating voltage deltas using an analog multiplexer (mux) 1102, which is shown to have two signal inputs, one control input and one signal output in this example. The control input receives a control signal (CTRL) which can be varied to connect, to the signal output, either the first signal input (selecting a voltage at the first signal input as output) or the second signal input (selecting a voltage at the second signal input as output). With voltages V₁>V₂ received at the signal inputs, a change in output voltage at the signal output can be generated by changing the voltage selection, either by flipping the input voltages between the signal inputs or via the control signal. Specifically, a positive voltage delta can be generated by selecting V₂ then selecting V₁. Likewise, a negative voltage delta can be generated by selecting V₁ then selecting V₂. In both cases, the absolute values of V₁ and V₂ are immaterial, and it only the difference between those voltages V₁−V₂ that is material. A zero-voltage delta is generated simply by maintaining a fixed voltage, whose value is immaterial.

Returning to FIG. 1A, the depicted arrangement is referred to as a “capacitive summing” architecture. Further details of capacitive summing are given in Appendix A at the end of this description. In brief, coupling any line to output line 104 via a coupling capacitor creates a capacitive coupling having a size that depends on the size (capacitance) of the coupling capacitor. Specifically, each voltage delta on such a line has a relative coupling strength determined by the ratio of its capacitor to a total capacitance of the output line 104. The capacitance of the output line, in turn, depends on the size of the output capacitor 108. Hence, in the case of the input lines 102, each input line 102-1 . . . 102-4 has a coupling strength to the output line 104 dependent on the size C_{in,1}, . . . , C_{in,4} of its input capacitor 106-1, . . . , 106-4 relative to the total capacitance of the output line 104.

As a consequence, voltage changes on the output line 104 depend on a weighted average (mean) of voltage changes on the input lines 102, written as

$$Δ {V}_{i n} = {\sum }_{i = 1}^{N} {c}_{i} Δ {V}_{i n , i} ,$$

with weights c₁, . . . , c₄ dependent on the input capacitances C_{in,1}, . . . , C_{in,4}. The weights c₁, . . . , c₄ are referred to as “intrinsic” weights, to distinguish from stored weights, Wᵢ, that are applied to the inputs in some implementations (see below). In the special case that the input capacitances are all equal to each other (meaning the input lines 102 have equal capacitive coupling strength), ΔVᵢₙ is proportional to the non-weighted sum of voltage changes on the input lines 102, ΔVᵢₙ∝ΣᵢΔV_{in,i}. More specifically, the analog computing architecture 100 can be configured so that Vᵢₙ is proportional to the (uniformly weighted) average of input voltage changes,

$$Δ {V}_{i n} ∝ \frac{1}{N} {\sum }_{i} Δ {V}_{i n , i}$$

(with all input capacitances having equal values equal such that cᵢ=1/N). In some implementations, ΔVᵢₙ is at least approximately equal to the average of the input voltage deltas but this is not a requirement. The following examples consider this special case, but the description applies equally to the more general weighted average case.

The above properties enable the circuit to be leveraged for analog computation, specifically to calculate an average of input values received on the input lines 102. The input values are represented as voltage changes on the input lines 102, and their sum is computed as a voltage change on the output line 104. More specifically, the voltage on the output line 104 (V_{BL}) is set by a combination of a pre-charge voltage (V_{P}) and the results of the calculation

$$Δ {V}_{i n} = {\sum }_{i = 1}^{N} Δ {V}_{i n , i} :$$

$${V}_{B L} = {V}_{P} + Δ {V}_{i n} .$$

The analog output vale is represented as the change in the voltage on the output line, ΔV_{P}, following pre-charging. In one implementation, a voltage change ΔV_{in,i} on any input line can take one of three possible values {ΔV,0,−ΔV}. In this case, the maximum and minimum values of ΔVᵢₙ are ΔV and −ΔV respectively. Note, this is true for any number of inputs N. The value of ΔVᵢₙ can change in increments of (1/N)ΔV (step size), which is also the smallest increment by which the output voltage delta ΔV_{BL} can change. As the number of inputs N increases, the step size decreases.

A key application of the depicted architecture 100 is performing matrix-vector multiplication (MVM) in the analog domain. An MVM between an input vector and a weight matrix involves calculating one or more weighted sums of elements of the input vector, weighted by corresponding elements of the weight matrix (one weighted sum per weight matrix column). With multiple weight matrix columns, respective weighted summations across the weight matrix columns are performed in parallel in the analog processing domain using parallel instances of the analog computing architecture 100, as described later. In brief, on each input line i, a stored weight Wᵢ is applied to an input value xᵢ. A special bit cell architecture is described below, which is configured to both store a weight Wᵢ and multiply the stored weight Wᵢ with an input value xᵢ received as a voltage delta ΔVₓ_{ᵢ} to generate an output voltage delta ΔV_{in,i} on an input line to which the bit cell is coupled. In this case, the voltage delta on the ith input line, ΔV_{in,i}, represents the result of multiplying the weight Wᵢ with the input value xᵢ, i.e., Wᵢxᵢ. In the above description, the voltage delta ΔV_{in,i} is also referred to as an input value (or more precisely its analog representation). The meaning of the term “input value” will be clear in context. Where useful to distinguish Wᵢxᵢ (represented by ΔV_{in,i}) from the xᵢ (represented by ΔVₓ_{ᵢ}), the former may be referred to as a weighted input value, or the latter may be referred to as an unweighted input value or, equivalently, an “activation” (in machine learning, an activation refers to an output of an activation function, e.g. at applied at one layer of a neural network feeding into another layer, such as a vector-matrix multiplication layer; whilst that is an important use case of the architecture of FIG. 1A, the “activation” terminology is used more generally herein to refer to an input, and does not imply any particular use case). In this case, ΔVᵢₙ is a weighted average of the inputs x₁, . . . , x_{N} (weighted by stored weights W₁, . . . , W_{N}). The distinction between stored weights and intrinsic weights arising from a mismatch in coupling capacitance between different input lines is again noted. The following examples assume matched coupling capacitances on the input lines 102, meaning the stored weights Wᵢ are the only source of non-uniform weighting.

In the case that the weight Wᵢ and the input xᵢ can each take one of three possible values {−1,0,1}, then Wᵢxᵢ can only take those same values, and ΔV_{in,i} is confined to values of {ΔV,0,−ΔV}. As explained below, this situation arises with a “trit” (ternary digit) number format. It is important to note that the analog computing architecture 100 is not limited in this respect, and can be extended to alternative number formats.

To convert an analog summation output on the output line 104 to a digital format, an analog to digital converter (ADC) stage 110 is shown coupled to the output line 108. The ADC stage 110 transforms the results of computations in the analog processing domain into a digital processing domain (130 in later figures).

As explained in detail below, the described embodiments combine low-resolution analog-to-digital conversion with retention and propagation of quantization errors in the analog domain. Analog inputs are received and processed in a serialized fashion over multiple computation cycles and residual quantization errors arising from low-resolution DAC are propagated between computation cycles in the analog domain. The low-resolution ADC generates a quantized digital output in the digital processing domain and an analog residual error in the analog processing domain.

The ADC stage 110 is shown to comprise a low-resolution ADC 112 coupled to the output line 104, and an analog feedback path 114 from the low-resolution ADC 112 returning to the output line 104. A node 116 is shown as a point at which the analog feedback path 114 connects back to the output line 104. A residual error from a previous cycle is represented as a voltage change ΔV_{FB} arising from the analog feedback path, and in this case the change in output voltage is given by ΔV_{BL}=ΣΔV_{in,i}+ΔV_{FB} (the output of the calculation in the current cycle, which is the sum of the inputs to the current cycle and the residual error propagated from the previous cycle).

The analog feedback path 114 of FIG. 1A feeds back a residual quantization error from a previous computation cycle to a current computation cycle as an additional voltage delta (ΔV_{FB}) on the output line, meaning the output value is now given by:

$$Δ {V}_{B L} = Δ {V}_{i n} + Δ {V}_{F B} .$$

Conceptually, the ADC stage 110 can be said to receive an input sequence of analog inputs (an analog input being an input voltage delta ΔVᵢₙ=Zi ΔV_{in,i} in a given computing cycle in this example). Each analog input is added to the residual error ΔV_{FB} from the previous cycle, resulting in ΔV_{BL}, which is quantized (resulting in a digital quantization output and a new analog residual error).

FIG. 1B schematically illustrates an example low-resolution quantization scheme that may be applied in the ADC stage 110, resulting in residual analog errors. The ADC 112 is configured to quantize values generated on the output line 104 based on a quantization threshold Q, and output the quantized values in a digital format (quantized digital output). The ADC 112 is intentionally chosen to be “low-resolution” in relation to the computations performed in the analog processing domain. In the depicted example, the voltage change ΔVᵢₙ on the output line 104 arising from the calculation can take one of five possible values (0,0.25ΔV,0.5ΔV,0.75ΔV,ΔV), although this is merely one possible implementation choice. This situation arises with four input lines when ΔV_{in,i} can take one of two possible values {0,ΔV}, represented on each input line 102-1, . . . , 102-4 as ΔV_{in,i} E {0,ΔV}. Note, this is a simplification of the example given above in which ΔV_{in,i} can take one of three possible values.

A ‘natural’ choice would be to match the ADC resolution to the resolution of this integer calculation (the step size of ΔVᵢₙ), with a quantization threshold of Q=0.25 ΔV, ensuring all possible output values can be captured without quantization error. However, instead, a larger quantization threshold Q is chosen, with Q=0.5 ΔV in this particular example. As shown, this means quantization errors can arise in the digital output. Those residual quantization errors are, however, retained in the analog domain and fed-back to the output line 104 (as voltage deltas) via the analog feedback path 114. In this example, the digital output can be characterized as a threshold count where a threshold count of M corresponds to an analog output of size M*Q (so, in this example, a threshold count of 1 corresponds to an analog output value of 0.5ΔV and a threshold count of 2 corresponds to an analog output value of ΔV). The threshold count that is output for a given actual value on the output line 104 corresponds to a value that may be different than the actual value. In that case, a non-zero residual error is retained on the output line 104 that is equal to the difference between the actual value and the value corresponding to the threshold count. In this particular example, the ADC 112 operates so that the value corresponding to the threshold count is equal to or less than (but not greater than) the actual value. However, this is merely one possible implementation choice.

The purpose of this setup is to enable multi-digit input vectors to be processed on the input lines 102 in a digit-serial fashion, using a low-resolution ADC 112 but with the ability to generate a high resolution final digital output (‘high’ resolution meaning higher than the resolution of the ADC). The motivation to reduce the resolution of the ADC 112 is severalfold. It enables its physical size and power consumption to be reduced, and its speed of operation to be increased. This reduction in ADC resolution would normally come at the cost of reduced resolution in the digital output. However, that tradeoff is avoided with the present setup. In brief, when summing input values at a given digit position, the digital output at that point may exhibit a quantization error, as per FIG. 1B. However, because that error is retained in the analog processing domain, it can be propagated to the next digit position (‘carrying’ the error in the arithmetic sense) so that it can be incorporated in the next calculation. To account for the relative significance (in the arithmetic sense) of those digit positions, the propagated error is appropriately scaled. This is described in greater depth below.

Although the architecture 100 of FIG. 1A is analog in nature, when its use is confined to calculations with a fixed step size (e.g., (1/N)ΔV as in the example of FIG. 1B), the analog outputs are also effectively quantized. This effective quantization within the analog processing domain can arise from an explicit pre-processing quantization step.

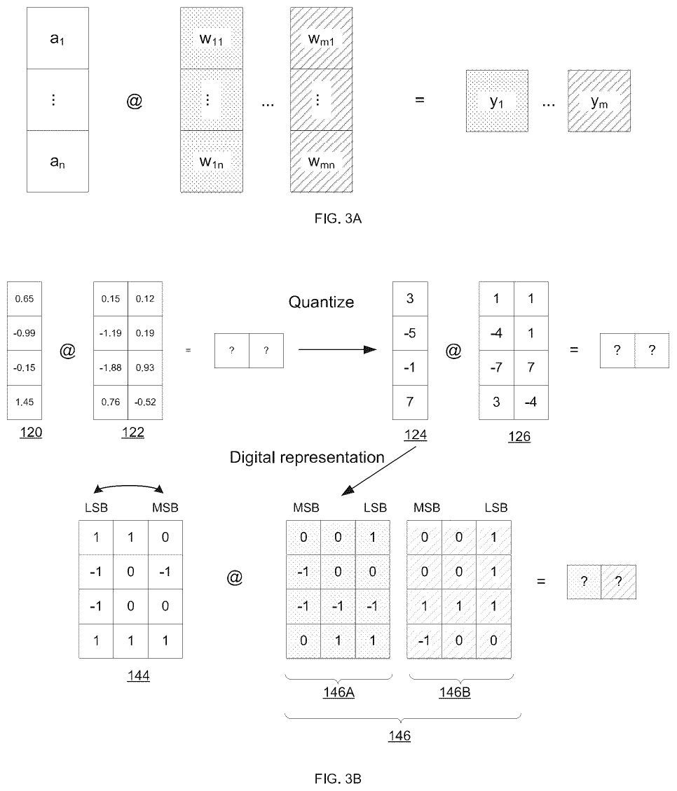

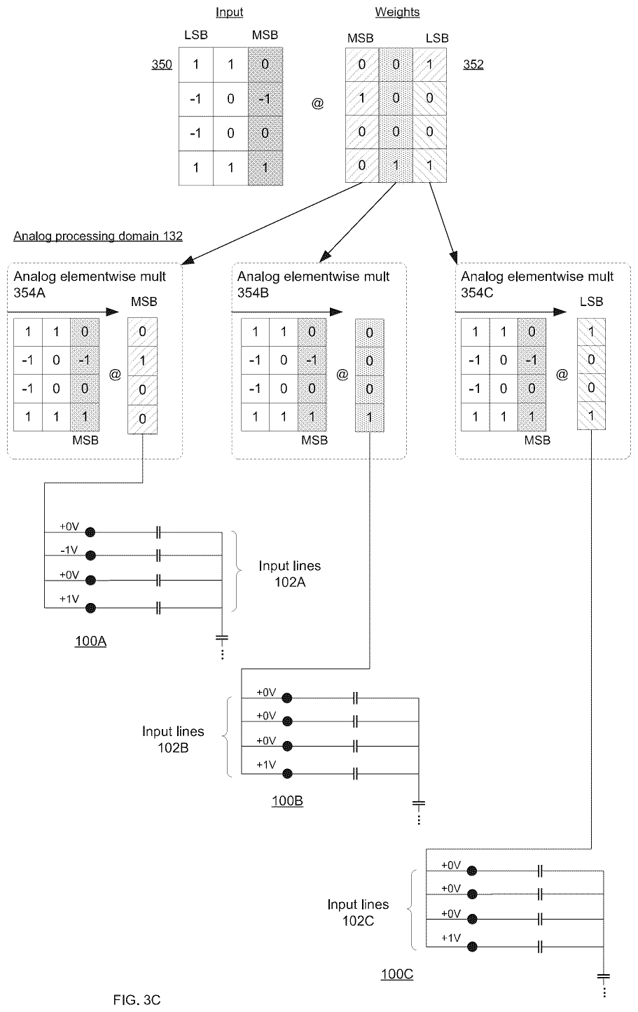

FIG. 1C illustrates by example a pre-processing input quantization step 129, which is shown in the context of an MVM to be performed in the analog processing domain. FIG. 1C shows a continuous-valued input vector 120 and continuous-valued weight matrix 122, which may for example be realized in computer storage, in the digital processing domain, using a floating-point number format. The continuous-valued weight matrix 122 has two weight columns in this example. However, this is merely an example, and in general a weight matrix can have any number of weight columns (including one). The terms weight column and weight vector are used interchangeably. Prior to processing in the analog processing domain 132, the continuous-valued input vector 120 and continuous-valued weight matrix 122 are quantized (129) to integer values in the range [−7,7], resulting in a quantized input vector 124 and quantized weight matrix 126 having, in this example, two quantized weight columns. Calculations in the analog processing domain 132 are performed on the quantized input vector 124 and quantized weight matrix 126. The analog computing architecture 100 of FIG. 1A is conducive to this operation, as it involves a weighted sum of the quantized input vector 124 over each weight column of the quantized weight matrix 126 (see FIG. 3C and accompanying description below for further details).

Although the input quantization step 129 is depicted as a single step for simplicity, in practice, the input vector 120 and weight matrix 122 may be quantized at different times. In various practical applications, the weight matrix 122 is determined in advance of the input vector 120. For example, in a machine learning context, the weight matrix 122 may be learned in a training phase, and quantized in advance of inference. The input vector 120, by contrast, may be quantized at the point it is received in at inference. Therefore, the input quantization step 129 may involve multiple phases performed at different times and/or on different computer devices.

Calculated outputs resulting from the MVM in the analog processing domain 132 are transformed back to the digital processing domain using low resolution analog-to-digital conversion of the kind described with reference to FIG. 1B based on output quantization 136. With quantized inputs, the resolution of the output quantization 136 is lower than the effective resolution of the analog computation output, which, in turn, is defined by the resolution of the input quantization 129. When applying the example quantization scheme of FIG. 1B, the resolution of the analog computation matches the resolution of the input quantization 129, and is twice the resolution of the output quantization 136.

Note, FIG. 1B is a simplification of an implementation described below, which extends this quantization scheme to accommodate negative input values (−1, 0, 1), meaning analog output values can be negative (e.g., represented as negative voltage changes). The broad principles of the ADC's operation remain the same.

One such implementation uses a trinary representation with three possible digit values (−1, 0, 1). In the digital processing domain 130, a digit is encoded as a bit pair (e.g., “00” to encode “0”, “10” to encode “1” and “01” to encode “−1”). In the analog processing domain 132, different digit values are represented as different voltage deltas As will become evident in the following description, this enables negative values to be naturally represented in a way that is particularly conducive to processing with the above setup. With this representation, the integer 3 is represented as (1,1) (same as binary) whilst the integer −3 is represented as (−1,−1). The term ‘bit’ may be sometimes used in this context to refer to a digit, notwithstanding that the more precise term for a digit in this representation is ‘trit’ (actually represented as a bit pair in the digital domain). Terms such as ‘bit-serial’ and ‘bit cell’ should, therefore, be interpreted appropriately broadly.

FIG. 1D shows an n-digit input vector 144 and k-digit weight matrix 146. In general, that terminology refers to an input vector with n-digit columns and a weight matrix with k-digit columns per weight column (k*m digit columns for a weight matrix with m weight columns). In this particular example, a trit representation is used to represent elements of the quantized input vector 124 and quantized weight matrix 126 of FIG. 1C. As those elements are integers in the range [−7,7] in this example, they can be embodied as 3-trit values using a 3-trit integer number format. Hence, in this example, n=k=3 and a digit has the form of a trit. In other words, the n-digit input vector 144 and k-digit weight matrix 146 are 3-trit representations of the quantized input vector 124 and the quantized weight matrix 126 respectively in this example, with three and six trit columns respectively. The n-digit input vector 144 is shown ordered from least significant digit (LSD) to most significant digit (MSD), whilst each weight column of the k-digit weight matrix 146 is shown ordered from MSD to LSD, for reasons that are explained later. FIG. 1D and the following description uses “most significant bit” (MSB) and “least significant bit” (LSB) terminology in this context, noting that more accurate terminology would be most/least significant trit for the specific example of FIG. 1D, and that the more general terminology is most/least significant digit. Whilst the following examples focus on this particular choice of 3-trit number format, the description applies equally to other choices of number format. More generally, the terms “n-digit” or “k-digit” may be used to refer to a scalar, vector, matrix etc. encoded using n or k digits (per element) of a chosen number format (e.g. bits, trits etc.). The term “digit column” refers to a column of single digits in the chosen number format. It is also noted that an input vector and a weight vector may be represented with different digit precision (e.g. different bit precisions, trit precision etc.), meaning a different number of digit columns may used to represent an input vector than a weight vector (that is, k≠n).

FIG. 1E shows a high-level data flow between the digital and analog processing domains, denoted by reference numerals 130, 132. An n-digit input vector 144 (3-trit in this example) is received and processed in the analog processing domain 132 in bit-serial fashion, over a series of computation cycles. In the present context, bit-serial (or, more precisely, trit-serial) fashion means the trit columns of the n-digit vector 144 are received and processed in series. Trit columns are passed to the analog processing domain 134 using a serial input mechanism 131. This means that only single-trit values are passed to the analog processing domain 132, which can be directly converted to corresponding analog values on the input lines 102 in the manner described above.

A weight digit column 147 (weight trit column in this example) is shown. The weight digit column 147 is multiplied with each digit column of the n-digit input vector 144. The following description refers to one computation cycle in relation to the processing of one input digit column (in practice, one such computation cycle could be performed over multiple clock cycles). Using the notation introduced above, each digit column of the n-digit input vector 144 has N elements, which are the inputs x₁, . . . , x_{N} to the relevant computation cycle, and the weight digit column 147 has N elements, which are the stored weights W₁, . . . , W_{N}. The inputs x₁, . . . , x_{N} change between computation cycles as the n digit columns of the n-digit input vector 144 are processed in series (meaning, in each computation cycle, ΔV_{in,i} is generated from a respective N input values received in that computation cycle), whereas the stored weights W₁, . . . , W_{N} do not change between computation cycles.

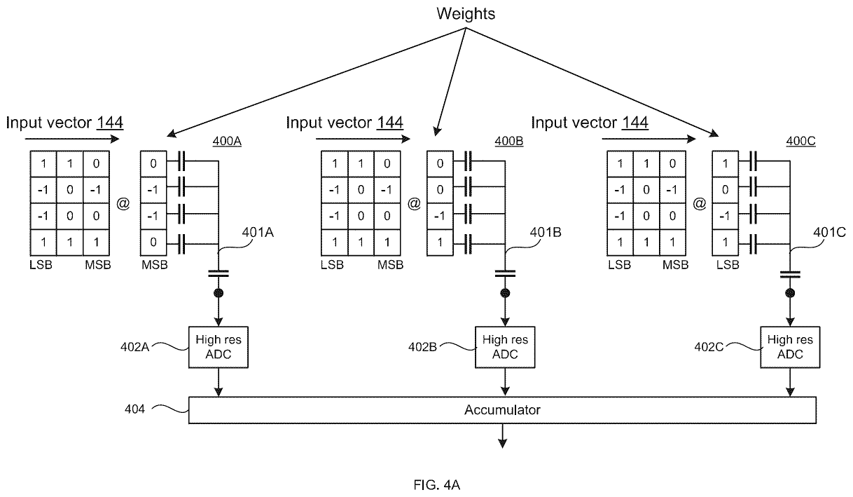

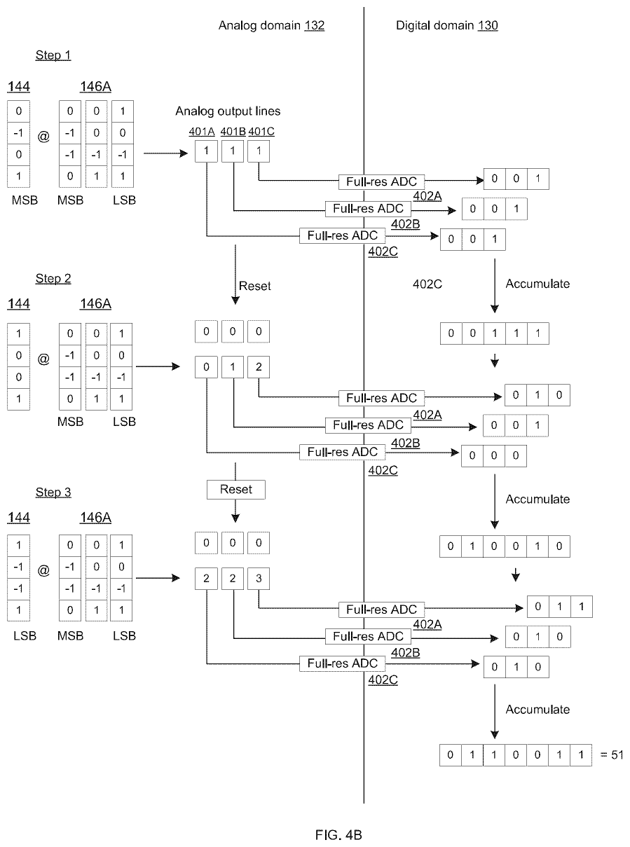

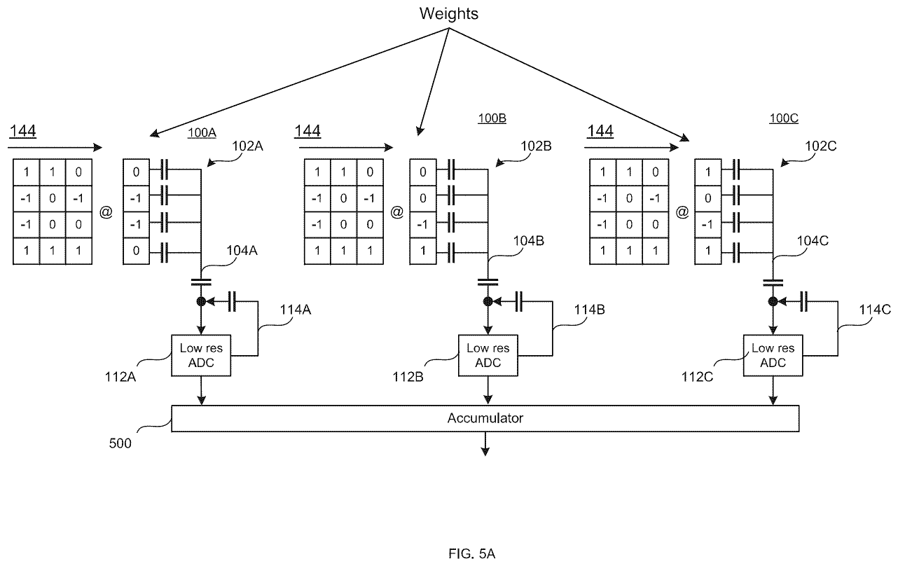

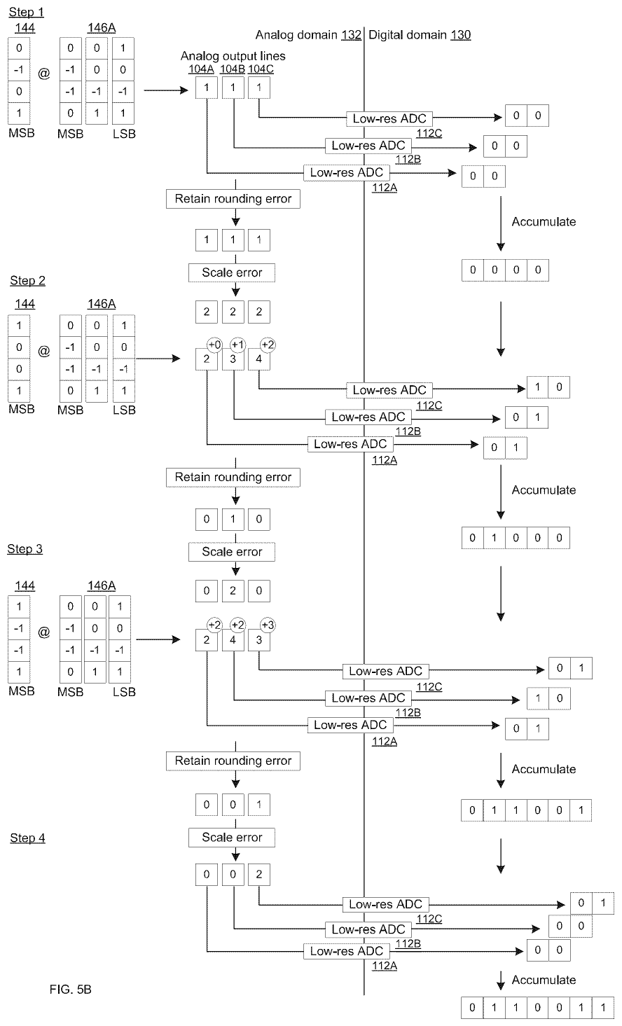

The weight digit column 147 is shown in FIG. 1D to belong to the k-digit weight matrix 146. In this case, each digit column of the n-digit input vector 120 is multiplied with each digit column of the k-digit weight matrix 146 in parallel. To perform multiplication across an entire k-digit weight matrix, k parallel instances of the analog computing architecture 100 are implemented per weight column of the k-digit weight matrix 146, and their outputs are accumulated to provide a single accumulated output per weight column (implying k*m parallel instances for a matrix with m weight columns, with m accumulated outputs in total). For a given n-digit input vector and k-digit weight column, outputs are accumulated over both the n digit columns of the n-digit input vector (processed in series over multiple computation cycles), and also across the k parallel instances of the analog computing architecture 100 (see FIGS. 4A-5B, described in detail below).

However, as discussed, there is no requirement for the digit precision of an input vector to match that of a weight vector, and in the extreme case, a weight vector may be represented as a single weight column (k=1). In this case, a multi-digit input vector may be multiplied with a single digit weight vector in digit-serial fashion, accumulating the outputs over the n digit columns of the input vector (processed in series), but with only a single instance of the parallel computing architecture 100 for the single digit column of the weight vector and therefore no accumulation across parallel instances.

FIG. 1E depicts the input quantization 129 in the context of the overall data flow. Input quantization 129 is applied to the input vector 120 to generate the n-digit input vector 144.

Analog processing 134 is applied to each digit column of the n-digit input vector 144 in turn, which in this example involves computing a weighted sum over that digit column (weighted by the weight digit column 147). As indicated, in the analog computing architecture 100, that weighted sum is a weighted average of the elements of the digit column. Analog-to-digital conversion is applied to the resulting output using low resolution output quantization 136, with any residual quantization error propagated (138) from an earlier computation cycle to a later computation cycle. ‘Earlier’ and ‘later’ mean relative to each other, and those terms may be similarly used in relation to the inputs/outputs of those computation cycles.

Error scaling 139 is used to scale the residual error to account for differences in the relative arithmetic significance of different bit positions. As explained below, scaling of residual error in the analog processing domain 136 is analogous to introducing a bit (or digit) offset in the digital domain 132 when accumulating digital outputs of different relative significance.

Further details of an analog matrix-vector multiplication architecture are described below. First some additional context to matrix-vector multiplication is described.

A matrix multiplication between an m×N matrix W and N-dimensional vector a results in an m-dimensional vector y, and has the following properties:

$$Wa = y ↔ {a}^{T} {W}^{T} = {y}^{T} ,$$

$$( \begin{matrix}{w}_{11} & … & {w}_{1 N} \\ ⋮ & ⋱ & ⋮ \\ {w}_{m 1} & … & {w}_{mN}\end{matrix} ) ( \begin{matrix}{a}_{1} \\ ⋮ \\ {a}_{N}\end{matrix} ) = ( \begin{matrix}a \cdot {w}_{1} \\ ⋮ \\ a \cdot {w}_{m}\end{matrix} ) = ( \begin{matrix}{y}_{1} \\ ⋮ \\ {y}_{m}\end{matrix} ) ,$$

$${w}_{j} = ( \begin{matrix}{w}_{j 1} \\ ⋮ \\ {w}_{jN}\end{matrix} ) ,$$

$${W}^{T} = ( \begin{matrix}{w}_{1} & … & {w}_{m}\end{matrix} ) = ( \begin{matrix}{w}_{11} & … & {w}_{m 1} \\ ⋮ & ⋱ & ⋮ \\ {w}_{1 N} & … & {w}_{mN}\end{matrix} ) .$$

Expanding on the above, the jth component of y is computed as a vector dot product (·) between a and an N-dimensional vector wⱼ corresponding to the jth row of W or, equivalently, the jth column of its transpose W^{T}. In other words, yⱼ is computed as a weighted sum of the components of a, weighted by the corresponding components of wⱼ:

$${y}_{j} = a \cdot {w}_{j} = {\sum }_{i = 1 , … N} {w}_{j i} {a}_{i} ∀ j = 1 , … , m .$$

The matrix W^{T} is referred to as a weight matrix herein, reflecting the above characterization of yⱼ as a weighted sum of the components of at.

The above MVM can be equivalently expressed as a dot product between a column vector of dimension N and a matrix of dimension N×m. An MVM between the N-dimensional column vector a and the N×m matrix W^{T} results in y^{T}, which is a 1×m output matrix or, equivalently, an m-dimensional row vector:

$$a \cdot {W}^{T} := {a}^{T} {W}^{T} = {y}^{T} ,$$

$$a \cdot {W}^{T} = ( \begin{matrix}{a}_{1} \\ ⋮ \\ {a}_{N}\end{matrix} ) \cdot ( \begin{matrix}{w}_{11} & … & {w}_{m 1} \\ ⋮ & ⋱ & ⋮ \\ {w}_{1 N} & … & {w}_{mN}\end{matrix} ) = a \cdot ( \begin{matrix}{w}_{1} & … & {w}_{m}\end{matrix} ) = ( \begin{matrix}a \cdot {w}_{1} & … & a \cdot {w}_{m}\end{matrix} ) = ( \begin{matrix}{y}_{1} & … & {y}_{m}\end{matrix} ) .$$

The above notation expresses an MVM in terms of column-wise operations and relationships: the jth output component yⱼ (in the jth output column) is given by the jth column of α·(w₁ . . . wₘ), which in turn is the vector dot product between the column vector a and the column vector wⱼ (the jth column of W^{T}).

With an n-digit input vector representation, an input vector a is represented as n digit columns (x₁ . . . xₙ) with each of those n digit columns containing N digits. With a k-digit weight vector representation, a weight vector wⱼ is represented as k digit columns (Wⱼ₁ . . . . Wⱼₖ) with each of those k digit columns containing N digits. For simplicity, the indexes are dropped elsewhere in this description so that an input digit column is denoted x=(x₁, . . . , x_{N}) and a weight digit column is denoted W=(W₁, . . . , W_{N}). As noted, in the analog computing architecture 100, it is actually the weighted average of x that is computed with respect to W, which is x·W/N in this notation. Note that elements of the weight matrix W are written in lower case notation with whereas digits of a k-digit weight column W are written in uppercase notation Wᵢ. In the following examples, the notation xᵢ denotes a single input/activation digit (e.g. a single digit of an n-digit input vector) and Wᵢ denotes a single weight digit (e.g. a single digit of a k-digit weight matrix).

As discussed, in certain implementations, a digital trit representation is used to represent input vectors and weight matrices. A dual bit cell architecture is described, which supports this representation.

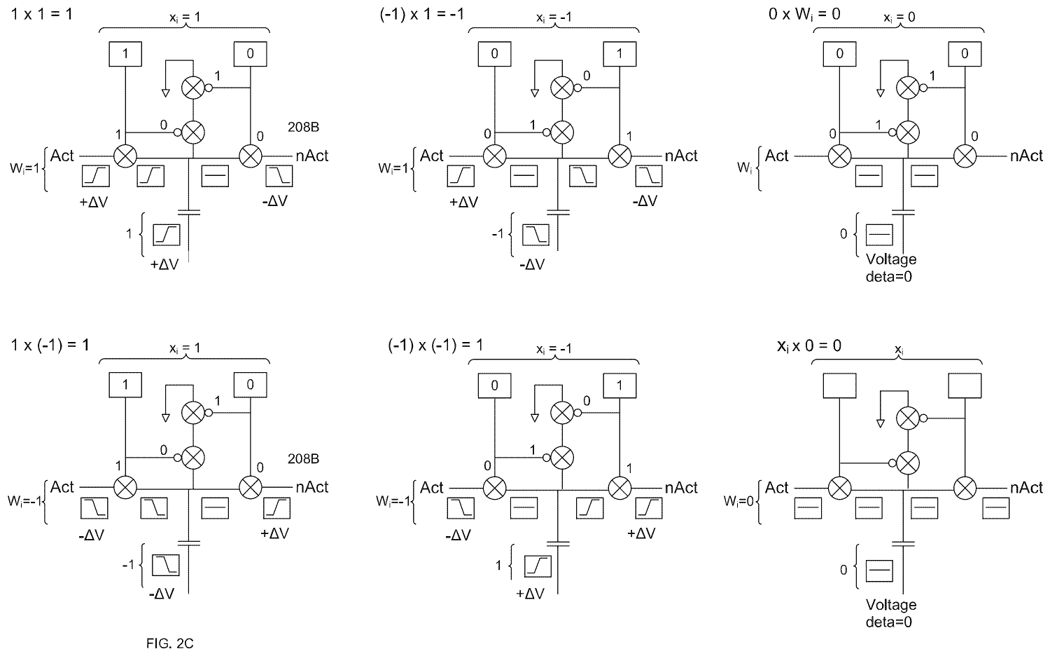

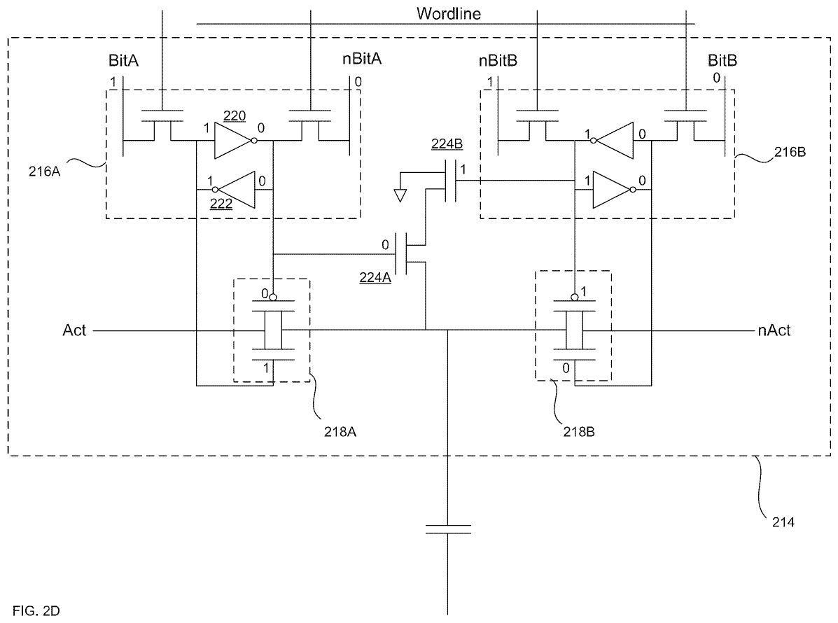

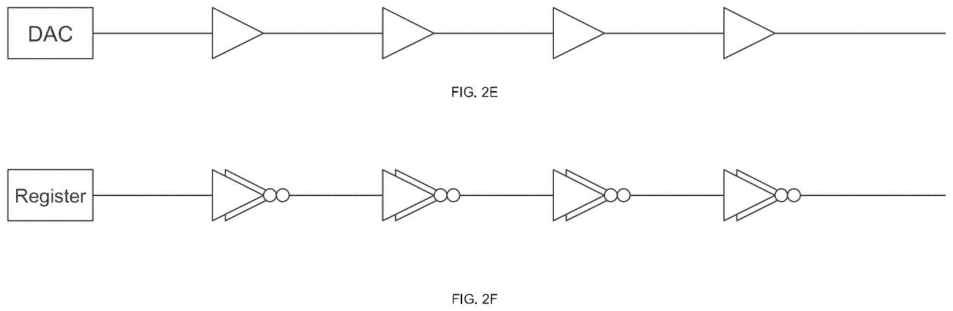

FIG. 2A shows an example of a dual bit cell, having two independently configurable states (first and second single bit cells 200A, 200B), which can be used to store trit values. In this example, a trit value of zero is stored as a bit pair 00. Trit values of +1 and −1 are stored as bit pairs 10 and 01 respectively.

As indicated above, there is an important distinction between how digits are stored and how they are represented on the input lines 102. Digits may, for example, be stored as bits or bit tuples (bit pairs in this example), but are represented on the input lines 102 as different voltage deltas in the cap active summing architecture of FIG. 1A (zero change, positive change, negative change in this example).

FIG. 2B shows a schematic circuit diagram of a storage-multiplication cell (SM cell) 202. The SM cell 202 provides digit storage with integrated analog computation (integrated analog multiplication in this example). The SM cell 202 is shown to comprise first and second bit cells 202A, 202B, first and second activation inputs 204A, 204B and a cell output 206.

A first pass gate 204A is shown, having a signal input connected to the first activation input 204A, a control input connected to the first bit cell 200A and a signal output connected to the cell output 206. The control input of the first pass gate 208A is configured so that, when the first bit cell 200A is in a “1” state, the first pass gate 208A is activated (connecting the first activation input 204A to the cell output 206), and when the first bit cell 200A is in a “0” state, the first pass gate 208A is deactivated (disconnecting the first activation input 204A from the cell output 206).

A second pass gate 204B is shown, having a signal input connected to the second activation input 204B, a control input connected to the second bit cell 200B and signal output connected to the volage output 206. The control input of the second pass gate 208B is configured so that, when the second bit cell 200B is in a “1” state, the second pass gate 208B is activated (connecting the second activation input 204B to the cell output 206), and when the second bit cell 200B is in a “0” state, the second pass gate 208B is deactivated (disconnecting the second activation input 204A from the cell output 206).

A third pass gate 210A and a fourth pass gate 210B are shown connected in series with each other. The third pass gate 210A has a control input connected to the first bit cell 200A and the fourth pass gate 210B has a control input connected to the second bit cell 200B. The control inputs of the third and fourth pass gates 210B, 210A are configured so that, when and only when both bit cells 200A, 200B are in the “0” state, both pass gates 210B, 210A are activated, thereby connecting the cell output 206 to a constant voltage (their control inputs are inverted relative to those of the first and second pass gates 208A, 208B). The constant voltage is ground in this example, but the following description applies equally to any constant voltage (constant throughout a computation cycle, resulting in a zero voltage delta in that cycle). In this example, the fourth pass gate 210B has an input connected to ground and an output connected to an input of the third pass gate 201A. However, the order of the pass gates 210A, 210B could equally be reversed. Note, in the case that both bit cells 200A, 200B are in the “0” state, the first and second pass gates 208A, 208B are both closed.

The bit cells 200A, 200B store a weight Wᵢ in digital format, specifically as (00,10 or 01) bit pair in this example. Alternative digital formats are considered later. An input value xᵢ is inputted as a pair of voltage changes at the first and second activation inputs 204A, 204B in the manner shown in Table 1 below. An input value of +1 is represented as a positive voltage delta (rising edge) at the first activation input 204A, an input value of −1 is represented as a negative voltage delta (falling edge) at the first activation input 204A and an input value of zero is represented as zero change in voltage at the first activation input 204A (no edge). At the second input 204B, an inverted voltage of equal magnitude but opposite sense (sign) is always applied. More generally, at the first input 204A, an analog representation of some input xᵢ is received, and at the second input 204B an analog representation of its additive inverse −xᵢ is received. In the figures, the voltage delta at the first input 204A is labelled Act (activation) and the voltage delta at the second input 204B is labelled nAct (NOT Act, meaning Act inverted).

TABLE 1

| Activation xᵢ | Act | nAct |
|---|---|---|
| xᵢ = +1 | +ΔV | −ΔV |
| xᵢ = −1 | −ΔV | +ΔV |
| xᵢ = 0 | 0 | 0 |

Depending on the pair of bits stored in the bit cells 200A, 200B, either the voltage delta at one of the activation inputs 204A, 2014B is selected, or neither is selected. In this context, ‘selected’ means the voltage delta in question is propagated to the cell output 206 via the first or second pass gate 208A, 208B. This mechanism is detailed in Table 2. Table 2 refers to the path to ground, which goes via the third and fourth pass gates 210A, 201B, and which is only closed when both pass gates 210A, 201B are closed. In relation to a pass gate, the term “activated” means the pass gate is in a first state such that its signal input is coupled to its signal output, thus providing a connection through the pass gate between its signal input and its signal output; “deactivated” means the pass gate is in a second state such that its signal input is decoupled from its signal output. This terminology does not imply any particular implementation of the pass gate.

TABLE 2

| Value of weight Wᵢ: | Wᵢ = 1 | Wᵢ = −1 | Wᵢ = 0 |
|---|---|---|---|
| Values of bit cells | 10 | 01 | 00 |
| 200A 200B: | | | |
| First pass gate 208A: | Activated | Deactivated | Deactivated |
| Second pass gate 208B: | Deactivated | Activated | Deactivated |
| Path to ground: | Deactivated | Deactivated | Activated |
| Selection: | First | Second | Ground path |
| | activation | activation | selected |
| | input 204A | input 204B | |
| | selected | selected | |
| Voltage delta at cell | Act | nAct | 0 |
| output 206: | | | |

The bit cells 200A, 200B are never placed in the “1” state simultaneously. Therefore, at any one time, the cell output 206 is only connected to a single one of the first activation input 204A, the second activation input 204B, or ground.

The SM cell 202 is shown with its cell output 206 connected to an input line 102-i with input capacitor 106-i on the input line 102-i (as in the architecture of FIG. 1A). In this arrangement, the weighted input value on the input line 102-i, ΔV_{in,i}, is either Act, nAct or 0, as per Table 2.

FIG. 2C demonstrates how the SM cell 200A calculates Wᵢxᵢ as a voltage delta on the input line 102-i. This is summarized in Table 3.

TABLE 3

| | Wᵢ = 1 | Wᵢ = −1 | Wᵢ = 0 |
|---|---|---|---|
| xᵢ = 1 | Act = +ΔV | nAct = −ΔV | Neither Act |
| | selected | selected | nor nAct |
| | (top left) | (top middle) | selected; zero |
| xᵢ = −1 | Act = −ΔV | nAct = +ΔV | voltage change |
| | selected | selected | input on line |
| | (bottom left) | (bottom middle) | (top right) |

| | |
|---|---|
| xᵢ = 0 | No voltage change applied at either |
| | activation input; zero change on input |
| | line (bottom right) |

On the input line 102-i, values of 1, −1 and 0 are represented as a rising edge (voltage delta of +ΔV), a falling edge (voltage delta of −ΔV) and no edge (voltage delta of zero). Hence, it can be seen from FIG. 2C and Table 3 that the correct multiplication result is generated on the input line 102-i for every possible combination of xᵢ and Wᵢ.

It is important to note that input values are represented as voltage deltas generated during the relevant computation cycle (e.g. using one of the mechanisms of FIG. 8), with the change in voltage occurring during that computation cycle. Changing the weight stored in the bit cells 200A, 200B may also cause voltage changes, however such operations are performed in separate programming cycles, meaning any such voltage changes do not take place during a computation cycle, and therefore do not affect the computation. More generally, voltages changes occurring outside of a computation cycle do not influence computation. In some implementations, an explicit pre-charge cycle is performed before each computation cycle that clears any remaining signal from either programming or from the previous computation cycle.

A weight is written to the bit cells 200A, 200B in a programming cycle. Once written to the bit cells 200A, 200B, a weight can persist for multiple computational cycles (e.g. applying the same weight to a stream of multiple input digits received and processed in digit-serial fashion).

In one implementation weight storage at the SM cell 202 uses a +1/−1 number format, with an extra bit of least-significant precision. The advantage is that the bit cell is considerably smaller (i.e. weight density is higher), although the per-cell capacitor will be smaller as a result. In order to be able to store a 0 weight, an n-bit weight can be stored using n+1 bit columns. The use of the extra bit means that there is a degree of redundancy in the encoding.

The SM cell 202 thus implements an in-memory analog compute architecture, specifically an in-memory analog signed arithmetic architecture (‘signed’ referring to the ability to incorporate positive and negative values). A weight persists in cell memory (the bit cells 200A, 200B in this example) as inputs are processed sequentially, and the stored weight is applied directly from the cell memory. The weight is stored in digital format and, beneficially, does not need to be converted to analog, which further simplifies the circuit, enabling its area to be reduced. Only the inputs need to be converted to analog, and the selection architecture enabled digital weights to be applied directly to analog inputs in memory.

A natural unit of compute for frontier models is the vector. Matrices of model weights multiply incoming vectors of data. However, almost all current hardware architectures—and software frameworks—are based around the idea of matrix-matrix multiplications instead, where a fixed-size batch of input vectors has to be gathered up and processed in parallel in order to extract maximum performance from the hardware. All frontier models follow some form of token-based processing, in which every word, image patch, or video frame, for instance, becomes a vector in a sequence. For generative architectures, vectors are also output, often in a sequential, autoregressive manner (one vector at a time). Much of the software complexity in current LLM inference solutions is because of attempts to reconcile this requirement for ideally having very fine-grained compute granularity with the hardware architecture's need to operate over fixed size batches and matrix-matrix multiplies. Often, a huge amount of performance is left on the table by the fundamental incompatibility of these two paradigms. Mature ecosystems have developed around prevalent hardware (such as GPUs) of patches, wrappers and third-party companies to try to overcome this.

By contrast, the architecture described herein natively operates on vectors at the hardware level, and so is inherently entirely efficient at the granularity of compute required for modern AI inference workloads.

Reference is made to our co-pending UK Patent Application No. GB2411004.1, the entire contents of which is incorporated herein by reference. Therein is described an in-memory analog computation architecture for vector matrix multiplication, in which a stream of input vectors is sequentially processed, so as to compute an output for each input vector before processing the next input vector in the stream, where the output is computed as a matrix multiplication of the input vector with a matrix read directly from the data memory. The SM cell 202 and ADC architecture described herein can be used to implement that approach, in the manner described herein.

FIG. 2D shows an example SRAM SM cell 214, which is one possible implementation of the SM cell 202 of FIG. 2B. The bit cells 200A, 200B are implemented as respective SRAM cells 216A, 216B, each comprising a bitstable flip-flop. This implementation incorporates SRAM storage, which is particularly conducive to manufacture in silicone. Another benefit of using SRAM is that the inverted controls for the third and fourth pass gates 210A, 201B can be extracted directly from SRAM bit cells, without requiring additional logic.

The bitstable flipflop of the first SRAM cell 216A is formed by a first inverter 220 and a second inverter 222 having an input connected to an output of the first inverter 220. A first bit input is connected to an input of the first inverter 220 and a second bit input is connected to the output of the first inverter 220. The bit inputs are connected via respective transistors controlled by a wordline. When the wordline closes the transistors, a bit can be read to each bit cell. The first bit input is set to the value to be read (BitA), and the second bit input is set to its inverse (nBitA). When the wordline closes the transistors, the bit written to the first SRAM cell 216A (BitA) persists at an output of the second inverter 222.

In this example, the first pass gate 208A is implemented as a first transistor pair 218A. The transistor pair 218A is formed of a p-channel transistor and an n-channel resistor connected in parallel with each other. A control terminal of the p-channel transistor is connected to the output of the first inverter and the input of the second inverter of the first SRAM cell 216A, meaning the p-channel transistor is controlled by nBitA, and is closed when nBitA=0 (implying BitA=1) and open when nBitA=1 (BitA=0). A control terminal of the n-channel transistor is connected to the input of the first inverter and the output of the second inverter of the first SRAM cell 216A, meaning the n-channel transistor is controlled by nBitA, and is closed when BitA=1 and open when BitA=0. Hence, either both transistors are open (BitA=0) or both are closed (BitA=1).

The second SRAM cell 216B is implemented in the same way as the first SRAM cell 216A and the description of the first SRAM cell 216A applies equally to the second SRAM cell 216B. The second pass gate 208B is implemented as a second transistor pair 218B in the same configuration as the first transistor pair 218A and connected to the second SRAM cell 216B in the same way.

The third pass gate 210A is implemented as a third n-channel transistor 224A having a control input connected to the output of the first inverter 220 of the first SRAM cell 216A. Note, it is the inverse bit value nBitA that persists at the output of the first inverter 220, meaning the n-channel transistor 224A is open when nBitA=0 (implying BitA=1), as desired.

The fourth pass gate 210B is implemented as a fourth n-channel transistor 224B having a control input connected to the second SRAM cell 216B in the same way.

So far, only analog-to-digital conversion of outputs has been discussed. A digital-to-analog converter (DAC) mechanism for converting inputs to SM cell 202 is now considered.

Processing input in bit (or trit) serial removing the need for any complex input analog-to-digital converter (DAC) on the input side.

FIGS. 2E-F shows possible digit serial input circuit that may be used in conjunction with the SM cell 202.

FIG. 2E shows a DAC configured to drive a chain of unity-gain buffers. The number of buffers is constrained by offset errors, and speed is constrained by load on each buffer and need to allow the voltage to settle. This is one possible mechanism to drive the activation inputs 204A, 206B of FIG. 2B (each input 204A, 206B is coupled to such a chain in this case).

FIG. 2F shows a preferred digit serial input circuit. A digital register drives a chain of (higher gain) digital buffers. Buffers can themselves include registers. There is no need in this case for long a settling time, meaning line delay can be significantly reduced. This input architecture enables activations to be carried over longer distances. To implement this input circuit in the architecture of FIG. 2B, the activation inputs 204A, 204B are coupled to respective chains of digital buffers, each of the kind shown in FIG. 2F. In other words, each activation input 204A, 206B is driven by its own chain of digital buffers.

In the above examples, where single trits are passed to the analog processing domain, minimum logic is needed for digital to analog conversion (and therefore minimum DAC circuit area), as the three possible trit values can be represented straightforwardly in analog using positive, negative and zero voltage deltas. In other number formats, a digit could have more than three values, which generally increases the complexity and therefore the size of the DAC circuit. For example, a digit comprised of three bits could have up to eight values, or a two-bit digit that additionally uses the 11 state could have up to four values. This generally requires more a complex DAC circuitry, although that may be an acceptable tradeoff in some contexts. Generally, ‘smaller’ digits (with smaller value ranges) are favored, although it will depend on the context.

Note that an input xᵢ is converted to an analog representation at the activation inputs 204A, 204B, e.g. using one of the voltage delta generation mechanisms of FIG. 8 applied to the digit serial input circuit of FIG. 2E or 2F. By contrast, a weight Wᵢ is stored in digital format at the SM cell 202, controlling the pass gates 208A, 208B, 210A, 201B to implement the multiplication operation. A benefit of the bit cell architecture is that the weight Wᵢ does not need to be converted to analog, and multiplication of the weight Wᵢ with an incoming input digit xᵢ is applied directly in memory at the SM cell 202.

FIG. 3A visualizes an MVM of the kind described above. Note, the figures use “@” to denote a dot product for improved visibility. Shading is used in FIG. 3A to visualize the column-wise relationships between the weight matrix W^{T} and the output y^{T}.

FIG. 3B shows an MVM to be performed on quantized digital inputs of the kind shown in FIG. 1D and described above. First, is it observed that the depicted calculation should yield the following result:

$$( \begin{matrix}3 \\ - 5 \\ - 1 \\ 7\end{matrix} ) \cdot ( \begin{matrix}1 \\ - 4 \\ - 7 \\ 3\end{matrix} ) = 51 \qquad ( 0 )$$

The aim is to perform this calculation on the 3-trit representations (or n-digit and k-digit representations more generally) in the analog processing domain 132:

$$( \begin{matrix}0 & 1 & 1 \\ - 1 & 0 & - 1 \\ 0 & 0 & - 1 \\ 1 & 1 & 1\end{matrix} ) \cdot ( \begin{matrix}0 & 0 & 1 \\ - 1 & 0 & 0 \\ - 1 & - 1 & - 1 \\ 0 & 1 & 1\end{matrix} ) = ?$$

The first matrix on the left-hand side is the 3-trit representation of the n-digit input vector 144 (ordered from LSB to MSB for reasons explained later), whilst the second matrix is the 3-trit representation of a first weight column 146A (ordered from MSB to LSB) of the k-digit weight matric 146, also referred to as the first weight vector 146A below.

To do so, the MVM is decomposed into separate MVMs between each trit column of the n-digit input vector 144 and each weight column. In this example, the n*m-digit weight matrix 146 has first and second weight columns 146A, 146B (m=2), each comprising three trit columns (n=3).

FIG. 3C shows a high-level schematic block diagram for an extension to the analog computing architecture 100 of FIG. 1A. An MVM between an n-digit input vector 350 and n-digit weight vector 352 (e.g. a weight column of a larger weight matrix) is considered. The MVM is decomposed into first, second and third elementwise multiplication stages 345A, 354B, 354C operating in parallel with each other, with one stage per trit (or other digit) column of the weight vector 352 (three in this case). In each parallel computation, trit (or other digit) columns of the input vector 350 are processed in series. In this example, three parallel computations are depicted, between an MSB column of the input vector and each trit column of the weight vector 352. In each parallel computation, an elementwise multiplication between the current input vector trit column and the applicable weigh trit column is computed in the analog processing domain 132, i.e., each element of the input vector trit column is multiplied with the corresponding element of the applicable trit column of the weight vector 352. Outputs of the first elementwise multiplication stage 354A take the form of voltage changes on a first set of input lines 102A belonging to a first instance 100A of the analog computing architecture 100 of FIG. 1A (not depicted in full). Those values on the input lines 102A are summed and the results converted from analog to digital. As can be seen, these voltages changes can take values of +1V, −1V, 0 where “V” is a predetermined voltage step that can take any chosen value. The second and third elementwise computation stages 354A, 354B are similarly coupled to first and second sets of input lines 102A, 102B within first second and third instances 100B, 100C of the analog computing architecture 100 respectively. The remaining trit columns of the input vector 350 are processed sequentially in the same way across the parallel computation stages.

Although not shown in FIG. 3A, each element-wise multiplication stage is implemented as an instance of the SM cell 202 of FIG. 2B (one for each weight digit). Each SM cell is coupled to the applicable input line, stores a digit of the input digit column currently being processed, and multiplies it with the weight digit applied at that SM cell. As the digit columns of the n-digit input vector 144 are processed in series, the input value stored at any given SM cell may change. However, the weight digit applied at each SM cell does not change.

Having computed MVMs between each trit column of an input vector and each trit column of a weight vector, the results need to be accumulated in a manner that accounts for the different relative arithmetic significance of those trit columns. To further illustrate this concept, it is useful to consider how the analog computing architecture 100 of FIG. 1A might alternatively be implemented using a ‘naïve’ high-resolution ADC mechanism, in place of the low-resolution ADC 112 with analog feedback of residual error of FIG. 1A.

FIG. 4A schematically illustrates a naïve analog MVM architecture, with three parallel instances 400A, 400B, 400C of capacitive summing circuits of the kind used in FIG. 1A, comprising respective output lines 401A, 401B, 401C. The three trit columns of the first weight vector 146A are distributed between the three instances of the capacitive summing circuits (one trit column of the weight vector per summing circuit). Each summing circuit processes all trit columns of the input vector 144 in serial fashion. In contrast To FIG. 1A, the ADC stage 110 is omitted, and instead the summing circuits 1004A, 400B, 400C are coupled to respective high-resolution ADCs 402A, 402B, 402C, which in turn are coupled to a digital accumulator 404.

FIG. 4B shows a schematic flow diagram illustrating the operation of the MVM architecture of FIG. 4A.

In a first processing step, an MVM between the MSB column of the input vector 144 and the first weight column 146A is computed:

$$( \begin{matrix}0 \\ - 1 \\ 0 \\ 1\end{matrix} ) \cdot ( \begin{matrix}0 & 0 & 1 \\ - 1 & 0 & 0 \\ - 1 & - 1 & - 1 \\ 0 & 1 & 1\end{matrix} ) = ( \begin{matrix}1 & 1 & 1\end{matrix} ) \qquad ( 1 )$$

In the flow of FIG. 4A, the outputs of equation 1 are encoded as analog values on the output lines 401A, 401B, 401C. As noted, the value calculated on the output lines is actually an average (rather than a sum) of the weighted input values. Hence, a “1” in this context implies a voltage delta of (1/N)Δ, i.e. a single voltage step in the above sense. Similarly, a “2” implies a voltage delta of two steps, (2/N)Δ, and so on. In other words, output values are expressed in the following examples in units of step size.

In a second processing step, an MVM between the middle trit column of the input vector 144 and the first weight column 146A:

$$( \begin{matrix}1 \\ 0 \\ 0 \\ 1\end{matrix} ) \cdot ( \begin{matrix}0 & 0 & 1 \\ - 1 & 0 & 0 \\ - 1 & - 1 & - 1 \\ 0 & 1 & 1\end{matrix} ) = ( \begin{matrix}0 & 1 & 2\end{matrix} ) \qquad ( 2 )$$

Again, in the flow of FIG. 4A, those results are encoded as analog outputs on the output lines 401A, 401B, 401C.

In a third processing step, an MVM between the LSB column of the input vector 144 and the first weight column 146A yields:

$$( \begin{matrix}1 \\ - 1 \\ - 1 \\ 1\end{matrix} ) \cdot ( \begin{matrix}0 & 0 & 1 \\ - 1 & 0 & 0 \\ - 1 & - 1 & - 1 \\ 0 & 1 & 1\end{matrix} ) = ( \begin{matrix}2 & 2 & 3\end{matrix} ) \qquad ( 3 )$$

In the above, the results of the MVMs on the right-hand side of equations 1 to 3 are written as integer values in the range [−4,4]. This choice reflects how they are computed in the analog processing domain, with an MVM between 4-dimensional vectors yielding an integer value between −4 and 4 that is directly encoded on the relevant output line in the analog processing domain 132.

At the end of each processing step, the values on the output lines are converted to digital values, at full resolution, by the high-resolution ADCs 402A, 402B, 402C. Those outputs are accumulated, accounting for the relative significance of the trit columns of the first weight vector 146A by introducing appropriate relative offsets between those digital values.

The digital outputs are also accumulated over the course of the above processing steps, and in this context it is necessary to account for the relative arithmetic significance of the trit columns of the input vector 144 with appropriate bit offsets.

The aforementioned conversion and accumulations operations are summarized as follows (bold formatting is used to visualize bits arising from conversion of accumulation, to visually distinguish from offset bits not in bold).

In step 1, the outputs for the MSB column of the input vector 144, calculated in the analog domain as per equation 1, are converted and accumulated across the bit columns of the first weight vector 146A:

$${\underbrace{( \begin{matrix}1 & 1 & 1\end{matrix} )}}_{Analog outputs of ( 1 )} \to {\underbrace{( \begin{matrix}0 & 0 & 0\end{matrix} )}}_{Reset analog output lines} + {\underbrace{( \begin{matrix}001 & 001 & 001\end{matrix} )}}_{High res digital outputs} \qquad ( 4 )$$

$$\begin{matrix}( \begin{matrix}0 & 0 & 0 & 0 & 1\end{matrix} ) \\ + \\ ( \begin{matrix}0 & 0 & 0 & 1 & 0\end{matrix} ) \\ + \\ {\underbrace{( \begin{matrix}0 & 0 & 1 & 0 & 0\end{matrix} )}}_{Outputs of ( 4 ) with offsets}\end{matrix} = {\underbrace{( \begin{matrix}0 & 0 & 1 & 1 & 1\end{matrix} )}}_{Accumulated digital output} \qquad ( 5 )$$

In equation 5, relative bit offsets between the digital on the left-hand side account for the relative arithmetic significance of the corresponding bit columns of the first weight vector 146A.

Moving to step 2, the calculated outputs of equation 2 for the next most significant bit column of the input vector 144 are converted across the bit columns of the first weight vector 146A:

$${\underbrace{( \begin{matrix}0 & 1 & 2\end{matrix} )}}_{Analog outputs of ( 2 )} \to {\underbrace{( \begin{matrix}0 & 0 & 0\end{matrix} )}}_{Reset analog output lines} + {\underbrace{( \begin{matrix}000 & 001 & 010\end{matrix} )}}_{High res digital outputs} \qquad ( 6 )$$

To accumulate these outputs with the accumulated out of step 1 (equation 2), a bit offset is introduced between the output of (5) and the output of (6) to account for the different relative significance of the corresponding bit columns of the input vector 144:

$${\underbrace{( \begin{matrix}0 & 0 & 1 & 1 & 1\end{matrix} )}}_{Output of ( 5 )} \to {\underbrace{( \begin{matrix}0 & 0 & 1 & 1 & 1 & 0\end{matrix} )}}_{Offset relative to ( 6 )} \qquad ( 7 )$$

$$\begin{matrix}{\overbrace{( \begin{matrix}0 & 0 & 1 & 1 & 1 & 0\end{matrix} )}}^{Output of ( 7 )} \\ + \\ ( \begin{matrix}0 & 0 & 0 & 0 & 1 & 0\end{matrix} ) \\ + \\ ( \begin{matrix}0 & 0 & 0 & 0 & 1 & 0\end{matrix} ) \\ + \\ {\underbrace{( \begin{matrix}0 & 0 & 0 & 0 & 0 & 0\end{matrix} )}}_{Outputs of ( 6 ) with offsets}\end{matrix} = {\underbrace{( \begin{matrix}0 & 1 & 0 & 0 & 1 & 0\end{matrix} )}}_{Accumulated digital output} \qquad ( 8 )$$

In equation 8, bit offsets across the inputs on the left hand side (the accumulated output from step 1 for the MSB column of the input vector 144, and the digital outputs read from the three output lines 401A, 401B, 401C for the next-most significant column of the input vector 144) account for both the relative significance of the bit columns of the input vector 144 between steps 1 and 2 and the relative significance of the bit columns of the first weight vector 146A.

The same principles apply as the method proceeds to step 3:

$${\underbrace{( \begin{matrix}2 & 2 & 3\end{matrix} )}}_{Analog outputs} \to {\underbrace{( \begin{matrix}0 & 0 & 0\end{matrix} )}}_{Reset analog output lines} + {\underbrace{( \begin{matrix}010 & 010 & 011\end{matrix} )}}_{High res digital outputs} \qquad ( 9 )$$

$${( \begin{matrix}0 & 1 & 0 & 0 & 1 & 0\end{matrix} )}_{Output of ( 8 )} \to {\underbrace{( \begin{matrix}0 & 1 & 0 & 0 & 1 & 0 & 0\end{matrix} )}}_{Offset relative to ( 9 )} \\ Accumulate ( 9 ) and ( 10 ) : \qquad ( 10 )$$

$$\begin{matrix}{\overbrace{( \begin{matrix}0 & 1 & 0 & 0 & 1 & 0 & 0\end{matrix} )}}^{Output of ( 10 )} \\ + \\ ( \begin{matrix}0 & 0 & 0 & 0 & 0 & 1 & 1\end{matrix} ) \\ + \\ ( \begin{matrix}0 & 0 & 0 & 0 & 1 & 0 & 0\end{matrix} ) \\ + \\ {\underbrace{( \begin{matrix}0 & 0 & 0 & 1 & 0 & 0 & 0\end{matrix} )}}_{Outputs of ( 9 ) with offsets}\end{matrix} = {\underbrace{( \begin{matrix}0 & 1 & 1 & 0 & 0 & 1 & 1\end{matrix} )}}_{Final digital output} = 51 \qquad ( 11 )$$

Equation 11 can be seen to yield the correct final output, matching equation 0.

As indicated, with k>1 (multiple digit columns per weight vector, as in the above example), the accumulator 404 accumulates both over the n digit columns of the n-digit input vector 144 and over the k parallel instances 400A, 400B, 400C. With k=1 (single digit column per weight vector), there is only a single instance of the capacitive summing circuit, and the accumulator 404 accumulates over the n digit columns of the n-digit input vector only.

FIG. 5A shows an alternative MVM architecture utilizing the analog computing architecture 100 of FIG. 1A. This architecture is capable of performing the same MVM calculations as that of FIG. 4A, with the same level of output precision, but using low-resolution analog-to-digital conversion.

FIG. 5A shows first, second and third analog computing circuits 100A, 100B, 100C, each having the architecture 100 described in FIG. 1A. In accordance with FIG. 1A, the analog computing circuits 100A, 100B, 100C comprise first, second and third sets of input lines 102A, 102B, 102C, coupled to first, second and third output lines 102A, 102B, 102C in a capacitive summing arrangement. Those output lines 104A, 104B, 104C are coupled to first, second and third ADCs 112A, 112B, 112C respectively. Those DACs 112A, 112B, 112C are low-resolution ADCs (in the above sense) supported by first, second and third analog residual error feedback paths 114A, 114B, 114C respectively. An accumulator 500 is shown having first, second and third inputs coupled to respective outputs of the first, second and third DACs 112A, 112B, 112C.

FIG. 5B shows a schematic flow diagram illustrating the operation of the MVM architecture of FIG. 5A. The flow begins with the analog output lines 104A, 104B, 104C in an initialized state denoted (0 0 0). As explained below, this is not necessarily a zero-voltage state, but can be characterized as a zero-residual error state.

In a first processing step, an MVM between the MSB column of the input vector 144 and the first weight column 146A is computed in the analog processing domain 132 (as per equation 1), yielding the following analog outputs on the output lines 104A, 104B, 104C:

$${\underbrace{( \begin{matrix}0 & 0 & 0\end{matrix} )}}_{Initialize analog outputs lines} \to {\underbrace{( \begin{matrix}1 & 1 & 1\end{matrix} )}}_{Add result of ( 1 )} \qquad ( 12 )$$

Again, for the reasons explained above, in this context, voltages deltas in the analog domain are written in units of voltage step size. In other words, a “1” in the analog domain means a voltage delta of

$$( \frac{1}{N} ) Δ V ,$$

i.e. a single voltage step. Likewise, a “2” means a voltage delta of

$$( \frac{2}{N} ) Δ V ,$$

i.e. two steps, and so on.

So far, this mirrors the flow of FIG. 4B. However, a difference can be seen at the end of the first processing step. Low-resolution analog-to-digital conversion is applied with a quantization threshold Q=2 (that is, 0.5 ΔV). As all of the values on the output lines 104A, 104B, 104C are below the quantization threshold Q, each DAC 112A, 112B, 112C generates a digital output of 0 in this particular example, with a residual quantization error of 1 remaining on each analog output line 104A, 104B, 104C:

$${\underbrace{( \begin{matrix}1 & 1 & 1\end{matrix} )}}_{Analog outputs of ( 12 )} \to {\underbrace{( \begin{matrix}1 & 1 & 1\end{matrix} )}}_{Analog residuals} + {\underbrace{( \begin{matrix}00 & 00 & 00\end{matrix} )}}_{Low res digital outputs} \qquad ( 13 )$$

The digital outputs are accumulated across the bit columns of the first weight vector 146A with offsets to account for the relative significance of those bit columns (which happens to be trivial in this specific example, as they are all zero, but this is not the case in general):

$$\begin{matrix}( \begin{matrix}0 & 0 & 0 & 0\end{matrix} ) \\ + \\ ( \begin{matrix}0 & 0 & 0 & 0\end{matrix} ) \\ + \\ {\underbrace{( \begin{matrix}0 & 0 & 0 & 0\end{matrix} )}}_{Digital outputs of ( 13 ) with offsets}\end{matrix} = {\underbrace{( \begin{matrix}0 & 0 & 0 & 0\end{matrix} )}}_{Accumulated digital output} \qquad ( 14 )$$

The residual errors remaining on the analog output lines 104A, 104B, 104C lines are then scaled via multiplication with a scale factor. A scale factor of two (meaning the residual errors are doubled) is used for reasons that are discussed below. Hence, in this example, the values on the output lines 104A, 104B, 104C are scaled to:

$${\underbrace{( \begin{matrix}1 & 1 & 1\end{matrix} )}}_{Analog residual output of ( 13 )} \to {\underbrace{( \begin{matrix}2 & 2 & 2\end{matrix} )}}_{Scaled analog residuals} \qquad ( 15 )$$

In a second processing step, an MVM between the middle trit column of the input vector 144 and the first weight column 146A is computed in the analog processing domain 132 as per equation 2. Whilst the computation is the same, the outcome differs from step 2 in FIG. 4B, as non-zero residual errors have been accumulated on the output lines 104A, 104B, 104C. The result of the MVM of step 2 is added to the scaled residual errors on the output lines 104A, 104B, 104C:

$${\underbrace{( \begin{matrix}2 & 2 & 2\end{matrix} )}}_{Scaled residuals of ( 15 )} \to {\underbrace{( \begin{matrix}2 + 0 & 2 + 1 & 2 + 2\end{matrix} )}}_{Add results of ( 2 )} = {\underbrace{( \begin{matrix}2 & 3 & 4\end{matrix} )}}_{Analog outputs} \qquad ( 16 )$$

At the end of step two, low resolution analog-to-digital conversion is again applied to each output line. With a quantization threshold of 2, the analog outputs on the first and second output lines 102A, 102B yield digital outputs of “1” (01), with a residual error of “1” remaining on the second output line 102B, whilst the analog output on the third transmission line 104C yields a digital output of “2” (10), with no residual error remaining on the first and third transmission lines 102A, 102C:

$${\underbrace{( \begin{matrix}2 & 3 & 4\end{matrix} )}}_{Analog outputs of ( 16 )} \to {\underbrace{( \begin{matrix}0 & 1 & 0\end{matrix} )}}_{Analog residuals} + {\underbrace{( \begin{matrix}01 & 01 & 10\end{matrix} )}}_{Low res digital outputs} \qquad ( 17 )$$

Applying the same principles as FIG. 4B, the low-resolution digital outputs are accumulated with the accumulated output of step 1 (which happens to be zero in this example), with appropriate bit offsets to account for both the different relative significance of the bit columns of the input vector 144 in steps 1 and 2 and the different relative significance of the bit columns of the first weight vector 146A:

$$\begin{matrix}{\overbrace{( \begin{matrix}0 & 0 & 0 & 0 & 0\end{matrix} )}}^{Output of ( 17 ) with offset} \\ + \\ ( \begin{matrix}0 & 0 & 0 & 1 & 0\end{matrix} ) \\ + \\ ( \begin{matrix}0 & 0 & 0 & 1 & 0\end{matrix} ) \\ + \\ {\underbrace{( \begin{matrix}0 & 0 & 1 & 0 & 0\end{matrix} )}}_{Digital outputs of ( 17 ) with offsets}\end{matrix} = ( \begin{matrix}0 & 1 & 0 & 0 & 0 & 0\end{matrix} ) \qquad ( 18 )$$

At the end of step 2, the analog residuals are scaled in the same way:

$${\underbrace{( \begin{matrix}0 & 1 & 0\end{matrix} )}}_{Analog residual output of ( 17 )} \to {\underbrace{( \begin{matrix}0 & 2 & 0\end{matrix} )}}_{Scaled analog residuals} \qquad ( 19 )$$

In step 3, an MVM between the LSB column of the input vector 144 and the first weight column 146A is computed in the analog processing domain 132 as per equation 3, and the results are added to the remaining residuals in the same manner:

$$\begin{matrix}\underbrace{( \begin{matrix}0 & 2 & 0\end{matrix} )} \\ Scaled residuals of ( 19 )\end{matrix} \to \begin{matrix}\underbrace{( \begin{matrix}0 + 2 & 2 + 2 & 0 + 3\end{matrix} )} \\ Add results of ( 3 )\end{matrix} = \begin{matrix}\underbrace{( \begin{matrix}2 & 4 & 3\end{matrix} )} \\ Analog outputs\end{matrix} \qquad ( 20 )$$

Low-resolution analog-to-digital conversion is applied again:

$$\begin{matrix}\underbrace{( \begin{matrix}2 & 4 & 3\end{matrix} )} \\ Analog outputs of ( 20 )\end{matrix} \to \begin{matrix}\underbrace{( \begin{matrix}0 & 0 & 1\end{matrix} )} \\ Analog residuals\end{matrix} + \begin{matrix}\underbrace{( \begin{matrix}01 & 10 & 01\end{matrix} )} \\ Low res digital outputs\end{matrix} \qquad ( 21 )$$

As in step 2, the resulting digital outputs are accumulated with the accumulated output of step 2, with appropriate bit offsets according to the same principles:

$$\begin{matrix}Output of ( 18 ) with offset \\ \overbrace{( \begin{matrix}0 & 1 & 0 & 0 & 0 & 0\end{matrix} )} \\ + \\ ( \begin{matrix}0 & 0 & 0 & 0 & 0 & 1\end{matrix} ) \\ + \\ ( \begin{matrix}0 & 0 & 0 & 1 & 0 & 0\end{matrix} ) \\ + \\ \underbrace{( \begin{matrix}0 & 0 & 0 & 1 & 0 & 0\end{matrix} )} \\ Digital outputs of ( 21 ) with offsets\end{matrix} = ( \begin{matrix}0 & 1 & 1 & 0 & 0 & 1\end{matrix} ) \qquad ( 22 )$$

Finally, to account for any final residual errors remaining at the end of step 3, in step 4, the remaining residuals are scaled a final time, with a final round of low-resolution analog-to-digital conversion:

$$\begin{matrix}\underbrace{( \begin{matrix}0 & 0 & 1\end{matrix} )} \\ Analog residual output of ( 21 )\end{matrix} \to \begin{matrix}\underbrace{( \begin{matrix}0 & 0 & 2\end{matrix} )} \\ Scaled analog residuals\end{matrix} \qquad ( 23 )$$

$$\begin{matrix}\underbrace{( \begin{matrix}0 & 0 & 2\end{matrix} )} \to \\ \end{matrix} \begin{matrix}\underbrace{( \begin{matrix}00 & 00 & 01\end{matrix} )} \\ Low res digital outputs\end{matrix} \qquad ( 24 )$$

$$\begin{matrix}Output of ( 22 ) with offset \\ \overbrace{( \begin{matrix}0 & 1 & 1 & 0 & 0 & \begin{matrix}1 & 0\end{matrix}\end{matrix} )} \\ + \\ ( \begin{matrix}0 & 0 & 0 & 0 & 0 & \begin{matrix}0 & 1\end{matrix}\end{matrix} ) \\ + \\ ( \begin{matrix}0 & 0 & 0 & 0 & 0 & \begin{matrix}0 & 0\end{matrix}\end{matrix} ) \\ + \\ \underbrace{( \begin{matrix}0 & 0 & 0 & 0 & 0 & \begin{matrix}0 & 0\end{matrix}\end{matrix} )} \\ Outputs of ( 24 ) with offsets\end{matrix} = ( \begin{matrix}0 & 1 & 1 & 0 & 0 & \begin{matrix}1 & 1\end{matrix}\end{matrix} ) = 51$$

Note, this yields the same final result in the digital domain as FIG. 4A (see equation (7) above), even though the resolution of the analog-to-digital conversion has been halved.

As indicated, with k>1 (multiple digit columns per weight vector, as in the above example), the accumulator 500 accumulates both over the n digit columns of the n-digit input vector 144 and over the k parallel instances 100A, 100B, 100C of the analog computing architecture 100. With k=1 (single digit column per weight vector), there is only a single instance of the capacitive summing circuit, and the accumulator 500 accumulates over the n digit columns of the n-digit input vector 144 only.

In this example, the number of inputs N=4, requiring only a single additional step (step 4) to achieve full precision in the final digital output. As N increases, the step size decreases, which may require multiple additional scaling and ADC steps to achieve full precision. If full precision is not required, these steps can be truncated to achieve any desired level of precision in the final output.

As noted, in the previously described examples, input vectors are processed in order of MSB column to LSB column. In bit-serial arithmetic there is a choice of whether to send bits in increasing order of significance (LSB-first) or in decreasing order of significance (MSB-first). Serial arithmetic usually uses LSB-first, as this fits with the natural direction of carry propagation and means that low-significance output bits cannot be changed as a result of processing a more significant bit. In turn, this means that the output of one bit-serial adder can be fed directly into another with no need for intermediate storage of a whole word.

However, for the current application, MSB-first has the following benefit. With MSB-first the residual error term is doubled when moving to the next input bit. With LSB-first it is halved (i.e. scale factor of 0.5), which can result in small errors that never get resolved because they always remain below the quantization threshold, reducing the accuracy of the final output. Moreover, if there are any inaccuracies in the feedback circuit that can accumulate over multiple cycles to cause bit errors then those errors will be in bits of lower significance with MSB-first processing. Whilst there are significant benefits to MSB-first processing, LSB-first processing is viable in situations where unresolved small residual errors are not a concern.

With regards to residual error scaling, each digit column has a significance weighting dependent on its relative position and the chosen number format. The scale factor applied to the residual error(s) at the start of a given computation cycle is equal to a relative significance weighting between the digit column processed in that computation cycle and the digit column processed in the previous computation cycle. The relative significance weighting is equal to the significance weighting of the digit column being processed in the current computation cycle divided by the significance weighting the digit column processed in the previous computational cycle. In the above example, each digit column has a significance of twice the previous digit column. With other number formats, different scaling factors can be applied. For example, if a base-three (or base-K) rather than base-two representation were used, the scaling factor would be three (or K) rather than two. With advances in machine learning, more complicated number formats are emerging. With some number formats, the relative significance weighting of adjacent digit positions will not necessarily be the same across the sequence. In such cases, different scaling factors would be applied in different computation cycles. Note, the scale factor depends on the relative significance of digit columns of an n-digit input vector processed in digit-serial fashion. The different relative significance of digit columns of a k-digit weight vector with k>1 is accounted for in the accumulator 500 (in the digital processing domain in the example of FIG. 5B).

Note, the example of FIG. 5B is simplified in the sense that the possibility of negative values on the output lines 102A, 102B, 102C is not considered. The possibility of negative values is addressed below, in the context of a specific implementation choice for the low-resolution ADC 112.

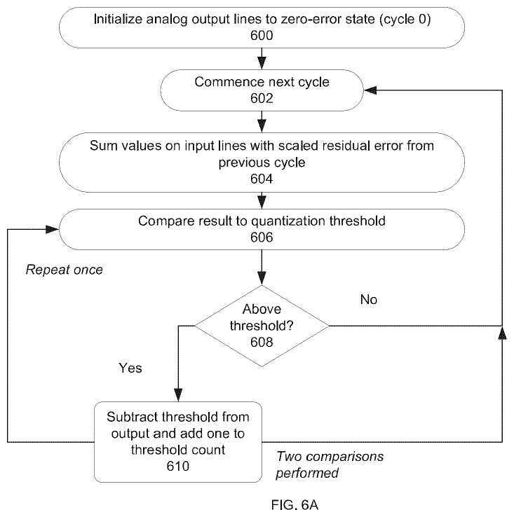

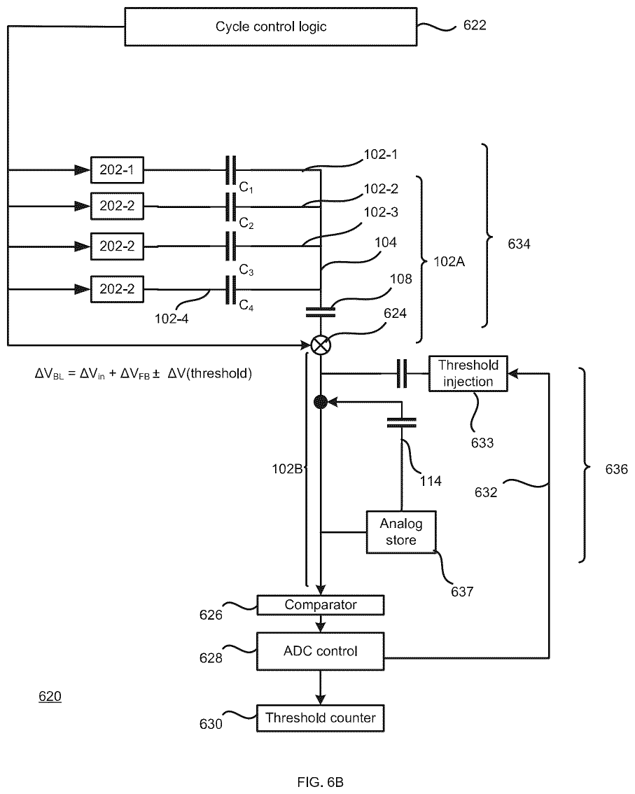

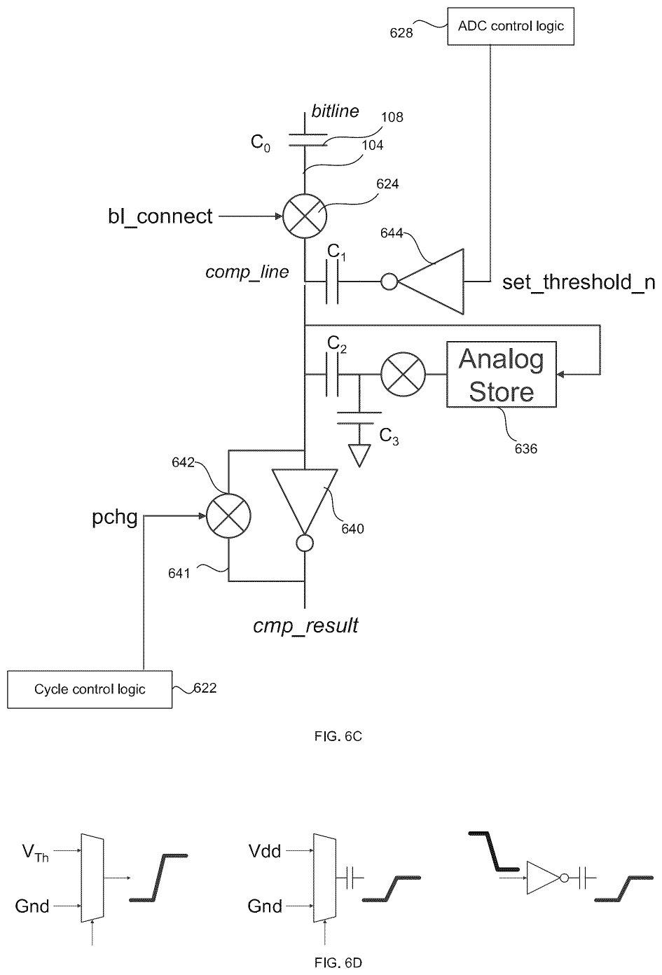

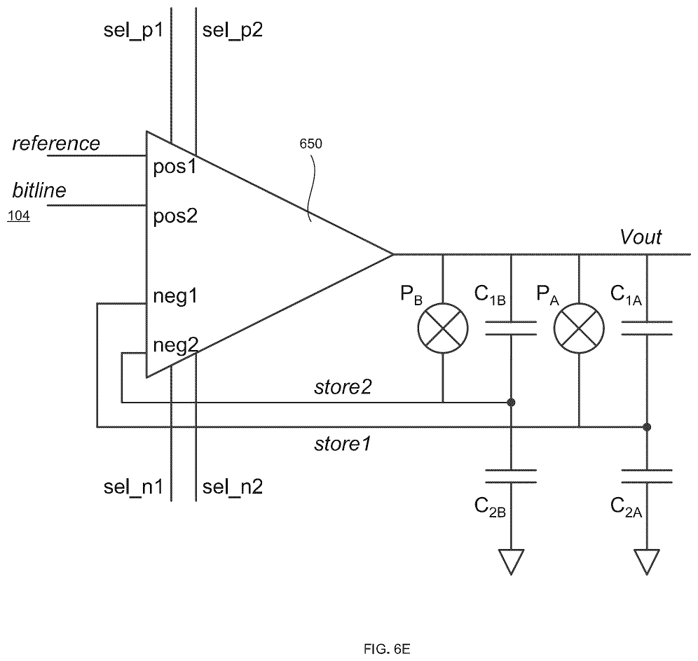

FIG. 6A shows a high-level flow chart for an analog-to-digital conversion method based on successive comparison and subtraction. This method reflects the operation of the low-resolution analog-to-digital converter 112 in one embodiment, and reflects the processing applied on a single output line.

At step 600 (cycle 0), the analog output lines 104A, 104B, 104C are initialized to a zero-error state. This is not necessarily a zero-voltage state, but can be any state representing zero residual error on each output line.

At step 602, the inputs are summed over all input lines 102 with a scaled residual error from the previous cycle (twice the residual error in the preceding examples). Step 602 is implemented at the hardware level in the capacitive summing architecture of FIG. 1A, which sums the values on the input lines with the residual error fed-back from the ADC 112.

At step 604, the result of step 602 is compared with a quantization threshold.

If, at step 604, the result is less than the quantization threshold, the method returns to step 602, commencing the next cycle with a new set of inputs on the input lines.

If, at step 604, the result is greater than the threshold (608, “Yes”), the method proceeds to step 610.

At step 610, a threshold count is incremented by one, and the threshold is additionally subtracted from the result of 602 to create a new result value.

In this example, from step 610, the method returns to step 606 once, i.e. there is one further threshold comparison. If the result of step 610 is still below the quantization threshold, the threshold count is incremented again (from one to two) and threshold is subtracted again. Repeating the comparison and subtraction prevents residual errors growing too fast as a result of scaling. Referring e.g. to step 2 of FIG. 5B, at the end of step 2, the value on the third output line 104C at the end of step 2 is “4” in units of voltage step size. With the implementation of FIG. 6A, this results in a threshold count of 1 at the first instance of step 610, and a value of 4−2=2 remaining on the third output line 104C at the second instance of step 610. Those operations are repeated, yielding a threshold count of “2” (10) and a residual error of 2−2=0. With larger scale factors, it may be appropriate to perform more than two rounds of comparison and subtraction.

FIG. 6B shows an example of a device 620 incorporating the analog computing architecture 100 of FIG. 1A. The device 620 is shown to comprise four SM cells 202-1, . . . , 202-4 (each of the kind described with reference to FIG. 2B), each of which is coupled to one of four input lines 102-1, . . . , 102-4 (with N=4 as in previous examples, but the description applying equally to other values of N). The input lines 102-1, . . . , 102-4 are capacitively coupled to an output line 104 with output capacitor 108 in the manner described with reference to FIG. 1. The output line 104 is shown to include an ADC pass gate 624 after the output capacitor 108. A first portion 102A of the output line 104 before the ADC pass gate 624, together with the other aforementioned components constitute an input circuit 634, which is coupled via the ADC pass gate 624 to a compute circuit 636 that includes a second portion 102B of the output line 104.

The compute circuit 636 is one possible implementation of the ADC stage 110 of FIG. 1. As such, the compute circuit 636 includes an analog feedback path 114 for propagating residual quantization errors between computation cycles. Within the compute circuit 636, the low-resolution ADC 112 of FIG. 1 is implemented as a combination of a comparator 626 having an input connected to an output of the ADC pass gate 624, an ADC control logic 628 having an input connected to an output of the comparator 626, a threshold injection circuit 633 and an analog data storage 636 (analog data store). The ADC control logic 628 has a first output connected to a threshold counter 630, a second output is coupled to the analog feedback path 114, and a third output connected to the threshold injection circuit 633. The analog store 637 has an input coupled to the second portion of the output line 104B (after the ADC pass gate 624) and an output connected to the analog feedback path 114, which in turn is capacitively coupled back to the second portion of the output line 104B (also after the ADC pass gate 624) in the manner described above. The threshold injection circuit 633 is also capacitively coupled to the output line 104, and controllable by the ADC control logic 628 to inject a threshold voltage delta ±ΔV (threshold). This means that a voltage change on the output line is now given by ΔV_{BL}=ΔVᵢₙ+ΔV_{FB}±ΔV (threshold). Here, ±ΔV (threshold) is the voltage delta that has the effect of either adding or subtracting the quantization threshold Q from the value represented on the output line as ΔV_{BL}. The analog store stores the scaled residual error from a previous computation cycle, and injects is back into a current computation cycle as ΔV_{FB}.

In order to process negative numbers (where the input from the SM cells 201-1, . . . , 201-4 could be negative), it is also necessary to compare to a negative threshold, and output a −1 (i.e. subtract 1 from the output) if the total is below the negative threshold. This is omitted from FIG. 6A for simplicity. Conceptually this means a sequence of four operations in total, implemented by the ADC control logic 628:
1) Compare to positive threshold (and selectively subtract dependent on result)
2) Compare to positive threshold a second time (and selectively subtract)
3) Compare to negative threshold (and selectively add dependent on result)
4) Compare to negative threshold a second time (and selectively add)

However, if the first positive threshold test fails then the second is unnecessary, and similarly for the negative threshold tests. Thus, in practice, only a maximum of three comparisons are actually needed.

The positive and negative thresholds are chosen to match in magnitude, otherwise positive and negative values are given different weights when calculating the output.

With negative values below the negative quantization threshold, the threshold is added to the result, rather than subtracted. To apply these operations consistently, it is necessary to determine whether the starting result is positive or negative. One way to achieve this is by extending the method of FIG. 6A as follows (in the following, ΔVᵢₙ denotes the sum of input voltage changes representing the input values, and the residual error is represented as a voltage change ΔV_{FB}):
1) ΔV_{BL}=ΔVᵢₙ+ΔV_{FB}−Δ(threshold)≥0==True (ΔVᵢₙ+ΔV_{FB} is greater than positive threshold):
   a) Add 1 to output;
   b) Subtract threshold from ΔVᵢₙ+ΔV_{FB} result to use as the feedback term in the next cycle (i.e., the ΔVᵢₙ+ΔV_{FB}−Δ(threshold) term becomes the new ΔV_{FB}).
2) ΔV_{BL}=ΔVᵢₙ+ΔV_{FB}−Δ(threshold)≥0==False (ΔVᵢₙ+ΔV_{FB} is less than positive threshold):
   a) Add 0 to output;
   b) Keep ΔVᵢₙ+ΔV_{FB} to use as the feedback term in the next cycle (i.e., ΔVᵢₙ+ΔV_{FB} becomes the new ΔV_{FB}).
3) ΔV_{BL}=ΔVᵢₙ+ΔV_{FB}+Δ(threshold)≤0==True (ΔVᵢₙ+ΔV_{FB} is less than negative threshold):
   a) Add −1 to output (or subtract 1 from the output);
   b) Add threshold to ΔVᵢₙ+ΔV_{FB} result to use as the feedback term in the next cycle (i.e. the ΔVᵢₙ+ΔV_{FB}+Δ(threshold) term becomes the new ΔV_{FB}).
4) ΔV_{BL}=ΔVᵢₙ+ΔV_{FB}+Δ(threshold)≤0==False (ΔVᵢₙ+ΔV_{FB} IS greater than negative threshold):
   a) Add 0 to output (or subtract 0 from the output);
   b) Keep ΔVᵢₙ+ΔV_{FB} to use as the feedback term in the next cycle.

The comparator 626 performs the comparison of ΔV_{BL} with zero in the above. The above comparisons can be implemented by subtracting (1 and 2) or adding (3 and 4) the threshold as applicable, and determining whether ΔV_{BL} is greater than (1 and 2) or less than (3 and 4) zero. In other words, the subtraction/addition of the threshold is actually done before the comparison. A “False” outcome at 2) implies the threshold has been “wrongly” subtracted, which is reversed straightforward by simply adding back the threshold to obtain the new ΔV_{FB} in 2b). This restored the original output value. Similarly, in the case of a “False” outcome at 4), the threshold has been wrongly subtracted, which is reversed by adding back the threshold. A benefit of this approach is that it can be implemented with minimal logic.

In an alternative implementation, the sequence is modified as follows, using an even number of phases. In alternate phases both the threshold and the analog error are multiplied by −1, which is achieved by changing the direction of the voltage edge through the relevant capacitor (i.e. instead of creating an edge between voltages V₁ and V₂, create one between V₂ and V₁). The logic that decides whether to output a 1 or −1 is also changed appropriately. The advantage of this is that it helps cancel out any systematic errors in the analog feedback path 114.
1) if there is a systematic offset in the storage circuit, then given an inputted a voltage V<the output will be V+offset
2) if the same value is passed around the circuit again, then the output will be V+offset+offset=V+2 offset, i.e. errors due to the offset accumulate with each pass through the storage circuit
3) However, the voltage is instead multiplied by −1 before the second pass, the output is −(V+offset)+offset=−V, i.e. the offset terms cancel and do not build up with each pass.

So, using an even number of phases removes this sort of systematic error. As noted above, only 3 phases are required to be able to handle both positive and negative values. However, a 4th phase can be added to achieve the cancellation, and this 4th phase can also be used to perform the scaling of the residual errors.

The cycle control logic 622 controls the SM cells 201-1, . . . , 201-4 to load new input values, and also controls the ADC pass gate 624 to selectively decouple the input circuit 634 from the compute circuit 636. For example, those circuits 634, 636 may be decoupled during a programming cycle whilst new inputs are written to the SM cells 202-1, . . . , 201-4.

As explained below, it is also, in fact, possible to implement the residual error scaling between compute cycles by decoupling those circuits 634, 636 temporarily.

FIG. 6C shows further details of part the compute circuit 636 in one embodiment. The comparator 626 is implemented as an inverter 636 (comparator inverter) and pre-charge loop 641 coupling the output of the inverter 640 back to its input via pre-charge pass gate 642, which is controllable by the control cycle logic 622 to open or close the pre-charge loop 641 via a pre-charge control signal (pchg).

Pre-charge and threshold comparison are implemented using the inverter 640 and pre-charge pass gate 642. When closed, the pass gate 642 connects the inverter output to its input (and therefore to the output line 104). During pre-charge, the closed pass gate 642 shorts the inverter terminals together, and sets the output line voltage to a switching point V_{P} of the inverter (the recharge voltage), meaning V_{BL}=V_{P} initially, as desired. After pre-charge the pre-charge pass gate connection is broken. When input, feedback and threshold voltage deltas are applied, the output voltage V_{BL} will move either up or down relative to the pre-charge voltage V_{P}, which in turn will cause the inverter output to move down or up respectively. In other words, the inverter 640 indicates which way the result of the comparison goes. A significant benefit of this arrangement is that the comparator circuit is self-referencing: the pre-charge voltage is automatically the balance point of the comparator, and there is no need for a separate comparator reference voltage.

The injection circuit 633 is also implemented as an inverter 644 (threshold inverter), which receives a threshold setting signal (set_threshold) from the ADC control logic 628. The inverter 644 is coupled to the second portion of the output line 204 (after the ADC pass gate 624) via coupling capacitor C₁ (threshold capacitor).

Referring briefly to FIG. 6D, the threshold voltage delta can be created in several ways. One way (shown at the left of FIG. 6D) is to use a voltage reference (V_{Th}) as one input to a mux and ground as a second input. A threshold delta is generated by switching between the two. Another way (middle of FIG. 6D) is to use a Gnd-to-Vdd voltage swing, and scale the threshold coupling capacitor (C₁ in FIG. 6C) to achieve a desired magnitude of threshold voltage delta. The second option is preferred, as it doesn't need a voltage reference, and allows the mux to be reduced to simpler logic shown on the right-hand side of FIG. 6D, namely an inverter and appropriately-scaled coupling capacitor, as in FIG. 6C.

In this case, a positive threshold delta is generated by flipping set_threshold from high to low. A negative threshold delta is generated by flipping set_threshold from low to high. In the examples described above, positive and negative threshold deltas are required to have equal magnitude. Another benefit of the implementation of FIG. 6C is that threshold deltas equal in magnitude but opposite in sense can be applied simply by switching between two predetermined input levels, without the need for calibration (if separate threshold injection circuits were used, they would need to be calibrated).

Although not depicted in FIG. 6C, multiple threshold magnitudes can be accommodated with parallel threshold inverters coupled with different size capacitors. One of these can be selected for a given computation.

The implementation of the analog store 637 is now considered with reference to FIG. 6E.

As discussed, feedback voltage that is needed as an input to the next computation cycle is derived from the output voltage at the end of the previous computation cycle. At the end of the previous computation cycle, the bitline voltage is given by one of:

$${V}_{BL} = {V}_{P} + ( {Δ V}_{in} + {Δ V}_{FB} ) + Δ ( threshold )$$

$${V}_{BL} = {V}_{p} + ( {Δ V}_{in} + {Δ V}_{FB} ) - Δ ( threshold )$$

$${V}_{BL} = {V}_{P} + ( {Δ V}_{in} + {Δ V}_{FB} )$$

The required feedback voltage for the next phase is given by ΔV_{FB}=V_{BL}−V_{P} in all cases. The relevant delta voltage can therefore be generated by a mux switching between V_{P} during pre-charge and the preceding V_{BL} during calculation.

The following pages therefore describe a combined amplifier and multiplexer implementation of the analog store 637 that can store two voltages and generate an edge equal to the difference between them.

FIG. 6E shows a schematic circuit diagram for such an implementation of the analog store 637. A combined multiplexor and operational amplifier (mux op-amp) 650 is shown, with two positive (non-inverting) inputs pos1, pos2 and two negative (inverting) inputs neg1, neg2. Selection inputs sel_p1 and sel_p2 enable one of pos1 (connected to the output line 104) and pos2 (connected to a reference voltage) to be selected, whilst selection inputs sel_n1 and sel_n2 enable one of neg1 and ned2 to be selected. Voltages are stored on storage lines. Two storage lines (store1, store2) are shown, allowing two voltages to be stored simultaneously. This enables a voltage difference to be captured as the difference between those two values, and the corresponding voltage delta to be generated on the output line 104 by switching between those values in a computation cycle (e.g. using one of the mechanisms of FIG. 8 applied to store1 and store2).

The output of the mux op-amp 650 is connected back to neg1 via capacitor C_{1A}, and to neg2 via capacitor C_{1B}. Pass gate P_{A} is connected in parallel with C_{1A}, enabling C_{1A} to be bypassed, providing a direct connection from the output to neg 1. Likewise, pass gate P_{B} is connected in parallel with C_{1B}, enabling C_{1B} to be bypassed, providing a direct connection from the output to neg 2. Capacitors C_{1A} and C_{1B} are connected in series with C_{2A} and C_{2B} respectively, which in turn are connected to ground.

Usually only one of the (pos1, pos2) inputs only one of (neg1, neg2) is selected at any one time. sel_[pn][12] are corresponding active-high select inputs, so only 1 of sel_p* will be high at any time (meaning they could be connected via an inverter), and similar for sel_n*. Capacitors C_{1A} and C_{1B} are nominally the same value (C₁), and similarly C_{2A}=C_{2B}=C₂. The ratio C₂/C₁ sets the amplifier gain. Capacitors C₁, C₂ are also used for value storage (“store 1” and “store 2” respectively) and input offset cancellation, by turning the pass gates P_{A}, P_{B} on and off.

The circuit operates as follows.

Initially, inputs pos1 (bitline) and neg1 (store1), are selected and passgates (P_{A}, P_{B}) are set to (on, off). The amplifier 650 operates as unity-gain buffer, Vout=bitline=store1. If P_{A} is then turned off, C_{2A} holds this voltage.

Next, inputs pos1 (bitline) and neg2 (store2), are selected and passgates (P_{A}, P_{B}) are set to (off, on). Amplifier 650 operates as unity-gain buffer, Vout=bitline=store2. If P_{B} is then turned off, C_{2B} holds this voltage.

The voltage on C_{2A} is also shifted at this point by any change in Vout since P_{A} was turned off:

$$Δ store 1 = {C}_{1} / ( {C}_{1} + {C}_{2} ) ΔV out = {C}_{1} / ( {C}_{1} + {C}_{2} ) Δ bitline = {C}_{1} / ( {C}_{1} + {C}_{2} ) ( {bitline}_{B} - {bitline}_{A} )$$

$$1 / α = {C}_{1} / ( {C}_{1} + {C}_{2} )$$

$$So store 1 = {bitline}_{A} + 1 / α ( {bitline}_{B} - {bitline}_{A} )$$

Next, inputs pos2 (reference) and neg2 (store2) are selected, with both pass gates off. The circuit now operates as feedback amplifier with gain α, =(C₁+C₂)/C₁.

Vout shifts so that ΔVᵢₙ=0, i.e. neg2→reference, so Δstore2=reference−bitline_{B}, meaning:

$$ΔV out = α Δ store 2 = α ( reference - {bitline}_{B} )$$

$$Δ store 1 = Δ store 2 , store 1 \to {bitline}_{A} + 1 / α ( {bitline}_{B} - {bitline}_{A} ) + ( reference - {bitline}_{B} )$$

$$store 1 = ( {bitline}_{A} - {bitline}_{B} ) ( 1 - 1 / α ) + reference$$

Finally, inputs pos2 (reference) and neg1 (store1) are selected, with both pass gates off. The circuit operates as feedback amplifier with gain α, =(C₁+C₂)/C₁.

Vout shifts so that ΔVᵢₙ=0, i.e. neg1→reference, which in trun means:

$$Δ store 1 = reference - ( ( {bitline}_{A} - {bitline}_{B} ) ( 1 - 1 / α ) + reference )$$

$$Δ store 1 = - ( {bitline}_{A} - {bitline}_{B} ) ( 1 - 1 / α )$$

$$ΔV out = α Δ store 1 = ( {bitline}_{B} - {bitline}_{A} ) ( α - 1 ) = ( {bitline}_{B} - {bitline}_{A} ) ( {C}_{2} / {C}_{1} )$$

Hence, the circuit can generate an output transition proportional to the difference in two stored input values, exactly as required.

More detailed analysis indicates that input offset terms cancel, provided that the offsets can be decomposed into terms associated with each individual input (e.g. due to VT offsets in the individual input transistors). Note that the gain for the output voltage delta is C₂/C₁, not the usual α=1+ (C₂/C₁). This is due to the shifting of one stored voltage while the other is processed. Other parts of this description use β=(C₂/C₁)=α−1 for this voltage delta gain. This edge depends on the ratio of C₁ and C₂, but not on the ratio of these capacitors to those elsewhere in the overall circuit—i.e. C₁ and C₂ don't need to track the other capacitors, so could in principle use a different layout if required, or be on different metal layer(s). The ‘reference’ voltage should be constant across the edge generation, but isn't required to be a particular voltage, and doesn't need to be the same for all columns.

The circuit, in fact, exhibits an ‘inverting’ behavior. In use, input A is the calculation result, and B the pre-charge voltage, so the output β(bitline_{B}−bitline_{A}) is negative if A is greater than B (the pre-charge level) and positive if A is less than B. This turns out to be a useful behavior, as offset voltages tend to cancel between successive iterations using the same circuit. If an even number of iterations is used then the sign of the signal is restored, and errors due to input offset voltages are reduced by this cancellation

Returning to FIG. 6C, the operation of the depicted circuits is considered with the analog store 637 implemented as in FIG. 6E.

Signal names are used in later description, and are as follows:
pchg—pre-charge enable.

$$1. High = connect inverter input and output ,$$

$$2. Low = seperate input and output .$$

set_threshold_n—threshold setting input (inverted).
cmp_result—output of comparator inverter.

The analog store 637 works as described previously with reference to FIG. 6E. it is coupled to the output line via capacitor C₂ (feedback capacitor).

In operation, bl_connect allows the first portion of the output line 104A (and its associated capacitance) to be disconnected from the second portion of the output line 104B, and hence from the compute circuit 636, which in turn changes a relative magnitude of the impact of the analog feedback path 114. This is a way to implement ‘multiply by 2’ in the feedback path (or more generally to apply a scaling factor) without needing a variable gain amplifier. In this implementation, the scale factor is applied by disconnecting the compute circuit 636 from the input circuit 634.

The relative size of C₁ and C₂ sets the threshold.

The value of C₂ together with the analog amplifier gain sets the analog feedback level.

C₀ is decoupling capacitor between bitline and compute circuit, which reduces the required size of C₁ and C₂ (see Appendix A for details).

An additional capacitor C₃ is shown connected between the analog feedback path 114 and ground. It is included to hold voltage when the pass gate on the analog feedback path 144 is off. Its value doesn't have to be related to any other capacitor.

Scaling by disconnecting from output capacitance

To implement scaling by a factor of two, C₁ and C₂ are chosen to have the same equivalent capacitance as the first portion of the output line 104A. The capacitance of the first portion of the output line is C₀ (the capacitance of output capacitor 108) plus any additional capacitance it exhibits. Doubling in the feedback loop can then be implemented by disconnecting the first portion of the bitline 104 (bl_connect=0), with no need for a separate scaling circuit. In this implementation the ADC pass gate 624 operates as an error scaling circuit.

Scaling factors other than two can be achieved by appropriate tuning of C₁ and C₂ relative to the output capacitance C₀. In one implementation, with a secured scale factor of S, the capacitances are tuned to provide a scale factor equal to the pth root of S. This means that, to apply the desired scale factor S, the circuit must be disconnected and reconnected p times (e.g. twice if the square root of s is chosen). This approach can be used to reduce overall scaling error. In analog circuitry, some level of noise is expected, which follows a noise distribution. If a high noise level is present during scaling by S directly, the high nose level will also be scaled by S. However, if scaling by a smaller amount multiple times, such ‘outlier’ noise levels have less impact (the probability of experiencing unusually high noise once is higher than experiencing unusually high noise p times).

It is also possible to implement error scaling in other ways, with a separate error scaling circuit (such as a variable gain amplifier).

### Circuit Operation

Circuit operation is divided into 4 phases. This is enough to cover the three necessary comparisons in the worst case. It is also an even number, so the inversions in the feedback path have cancelled before starting to process the next input. Note that it would also be possible to only use 3 phases, and invert the inputs in different phases.

Each phase is divided into 4 sub-phases, summarized in Table 4, to perform the calculation in that phase. The 4 sub-phases are:
1. Precharge part 1, store the pre-charge value;
2. Precharge part 2, initialize feedback and threshold circuits (i.e. drive their initial levels);
3. Calculation part 1—drive final levels of feedback and threshold circuits;
4. Calculation part 2—remove threshold (if necessary), update stored calculation result.

TABLE 4

| Sub- | +ve input | −ve input | Passgate | Passgate | |
|---|---|---|---|---|---|
| phase | source | source | P_{A} control | P_{B} control | Notes |
| 1 | bitline | store2 | off | on | Precharge bitline, and store bitline |
| | | | | | value. |
| 2 | reference | store2 | off | off | Feedback path drives initial value |
| | | | | | during pre-charge. |
| 3 | reference | store1 | off | off | Start of computation, feedback path |
| | | | | | switches to driving stored compute |
| | | | | | result. |
| 4 | bitline | store1 | on | off | Result of current computation is |
| | | | | | captured. |

The four sub-phases operate as follows. The description of the four sub-phases refers to the input voltage delta ΔVᵢₙ. In fact, it is only in Phase 1 that ΔVᵢₙ is generated on the output line 104 by the input circuit 634. In Phases 2 and 2, the input circuit 634 remains coupled to the compute circuit 636, but it does not generate any input voltage delta. In phase 4, the input circuit 634 is decoupled from the compute circuit 636 by deactivating the ADC pass gate 624.

Sub-phase 1: The passgate 642 around comparison inverter 640 makes input-to-output connection, hence, the output line 104 is forced to V_{P}. The output line pre-charge voltage V_{P} is stored in store2.

Sub-phase 2: Amplifier 650 then disconnects from bitline 104, and uses reference voltage as input. The amplifier output is initial value for feedback voltage delta. The threshold circuit 644 also switches to initial state. This completes the pre-charge.

Sub-phase 3: The connection around comparison inverter 640 via passgate 642 is broken, meaning bitline 104 starts floating at V_{P}. Amplifier 650 is used to generate voltage delta ΔV_{FB} by switching its output from store2 (holding V_{P}) to store1 (which holds V_{P}+ΔV_{FB} from the previous computation cycle, as explained below). Threshold circuit 644 also switches from its initial to final level, thereby generating either +Δ(threshold) or −Δ(threshold). The bitline voltage therefore shifts to V_{P}+ (ΔVᵢₙ+ΔV_{FB})+Δ(threshold) in Phase 1 and to V_{P}++ΔV_{FB}+Δ(threshold) in all other Phases. The output of the comparison invertor 640 then goes high or low to indicate the result of the comparison. At the end of this sub-phase, the inverter output is latched.

The inverter output and the form of comparison (i.e. to +ve or −ve threshold) together define whether 1, 0, or −1 should be added to the output. If 0 should be added, the threshold voltage delta is added/subtracted to the output to reverse the previous subtraction/addition. The inverter output also determines what the operation (add or subtract threshold) should be in the next phase.

Sub-phase 4: Amplifier 650 is switched to input from bitline 104, in order to capture the calculation result. If the calculation result is a “does not exceed threshold” then the threshold is subtracted or added from the bitline 104, meaning the threshold circuit switches back to its initial level. The calculation result is represented as a voltage delta ΔVₒᵤₜ on the output line 102 relative to the pre-charge voltage V_{P}. This voltage delta ΔVₒᵤₜ has one of three values. In Phase 1, those three values are V_{P}+ (ΔVᵢₙ+ΔV_{FB}), or V_{P}+ (ΔVᵢₙ+ΔV_{FB})+Δ(threshold). In all other phases, those three values are V_{P}+ΔV_{FB}, or V_{P}+ΔV_{FB}+Δ(threshold) (with ΔV_{FB} being a scaled term in Phase 4). The voltage on the output line 104 at the end of sub-phase 4 is V_{P}+ΔVₒᵤₜ, and this voltage is captured in the store1, retaining the captured pre-charge voltage V_{P} in store 2. By capturing both the pre-charge voltage V_{P} in sub-phase 1 and the final voltage V_{P}+ΔVₒᵤₜ in sub-phase 4, the calculation voltage delta ΔVₒᵤₜ is captured in the analog store as the difference between store1 and store2.

Each computation cycle is made up of Phases 1 to 4. In a given computation cycle, the voltage delta ΔVₒᵤₜ captured in sub-phase 4 of Phase 1 becomes the feedback voltage delta ΔV_{FB} in sub-phase 3 of Phase 2, and so on up to Phase 4. Between computation cycles, the final voltage delta captured in sub-phase 4 of Phase 4 at the end of a computation cycle becomes the feedback voltage delta ΔV_{FB} in sub-phase 3 of Phase 1 of the next computation cycle. In all cases, the required voltage change ΔV_{FB} is generated in sub-phase 3 by switching the output of the analog store 634 from V_{P} held in store2 to V_{P}+ΔVₒᵤₜ held in store 1. Note, the arrangement of FIG. 6E means the pre-charge voltage V_{P} is, by definition, the switching point of the comparison inverter 640, meaning the analog feedback store 636 is inherently calibrated with the comparator inverter 640.

The above sub-phases are implemented in each of phases 1 to 4 as follows.
Phase 1: Phase 1 (like all other phases) is made up of 4 sub-phases, as described previously. Phase 1 is the input phase, which means that the input voltage deltas are initialized during a pre-charge sub-phase (sub-phase 2) and applied during a calculation sub-phase (sub-phase 3), and the feedback voltage is applied (with a relative weight of 1) during a calculation sub-phase (sub-phase 3). The form of comparison (whether to compare to the positive or negative threshold and therefore whether to subtract or add Δ(threshold)) can either be reset at the start of the phase, or use the result left over from the previous phase of the previous computation cycle.
Phases 2 & 3: Phases 2 and 3 are identical to each other, and are each made up of 4 sub-phases. Phases 2 and 3 are not input phases, so the input voltage deltas are not applied (i.e. there are no input changes outside the pre-charge sub-phases). The feedback voltage is applied with a relative weight of 1 during the calculation sub-phases. The form of comparison (whether to compare to the positive or negative threshold, and therefore whether to subtract or add Δ(threshold)) is determined by the result of the previous phase. The voltage remaining on the output line 104 at the end of phase 3 (residual voltage) is stored in store 1. Together with the pre-charge voltage stored in store2, this captures the residual quantization error as the difference between those two voltages.
Phase 4: Phase 4 is also made up of 4 sub-phases. Phase 4 is used for the multiplication-by-2 (or scaling more generally) of the residual error before the start of the next input bit. The ADC pass gate 624 remains deactivated throughout phase 4 such that the compute circuit 636 remains decoupled from the input circuit 634 throughout. Sometimes this enables an early extraction of an output bit for the next bit position. Phase 4 is not an input phase, so the input voltage deltas are not applied (i.e. there are no input changes outside the pre-charge sub-phases). The feedback voltage is applied with a relative weight of 2 (or, more generally, S, set in the manner described above) during the calculation sub-phases. In this decoupled state, switching the output of the analog store 636 from store2 to store1 generates a voltage delta of S*ΔV_{FB} on the output line 104. In this example, Phase 4 also involves a threshold comparison. The form of comparison (whether to compare to the positive or negative threshold and therefore whether to subtract or add Δ(threshold)) is determined by the result of the previous phase. If the scaled residual error S*ΔV_{FB} is above +Δ(threshold), this will increment the threshold count for the next digit position, and if it is below −Δ(threshold), this will decrement the threshold count for the next digit position (this is the early extraction referred to previously). The remaining voltage on the output line (scaled residual voltage)—which, in this case is S*ΔV_{FB}, S*ΔV_{FB}+Δ(threshold) or S*ΔV_{FB}−Δ(threshold)—is captured back to the analog store 636 in sub-phase 4 of Phase 4. The next computation cycle then commences, with the threshold counter for the current digit position being 1, 0 or −1.

In an alternative embodiment, early extraction is not attempted in Phase 4. In this case, the compute circuit 636 is decoupled from the input circuit 634 in the same way. Sub-phases 1 and 2 are still performed to capture the pre-charge voltage, and the voltage delta S*ΔV_{FB} is generated in the output line 104 in the same way, but the voltage on the output line (ΔV_{P}+S*ΔV_{FB}) is simply stored back to the analog store 636 without any threshold comparison, enabling the scaled residual error S*ΔV_{FB} to be generated on the output line 104 again in the next compute cycle but with the ADC pass gate 624 now active, and the compute circuit 636 recoupled to the input circuit 634.

When processing a multidigit input vector over multiple computation cycles, ΔV_{FB} is set to zero initially, which can for example be achieved by storing V_{P} or any other voltage in both store1 and store 2. As noted above, the quantization process can be truncated, meaning that ΔV_{FB} can still be non-zero when the processing of a given input vector terminates. When processing multiple input vectors in serial fashion, ΔV_{FB} is re-set to zero to avoid propagating residual errors between different input vectors.

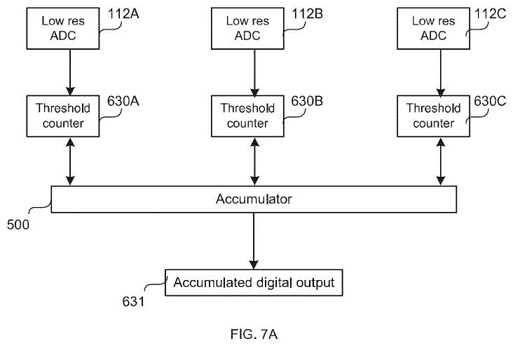

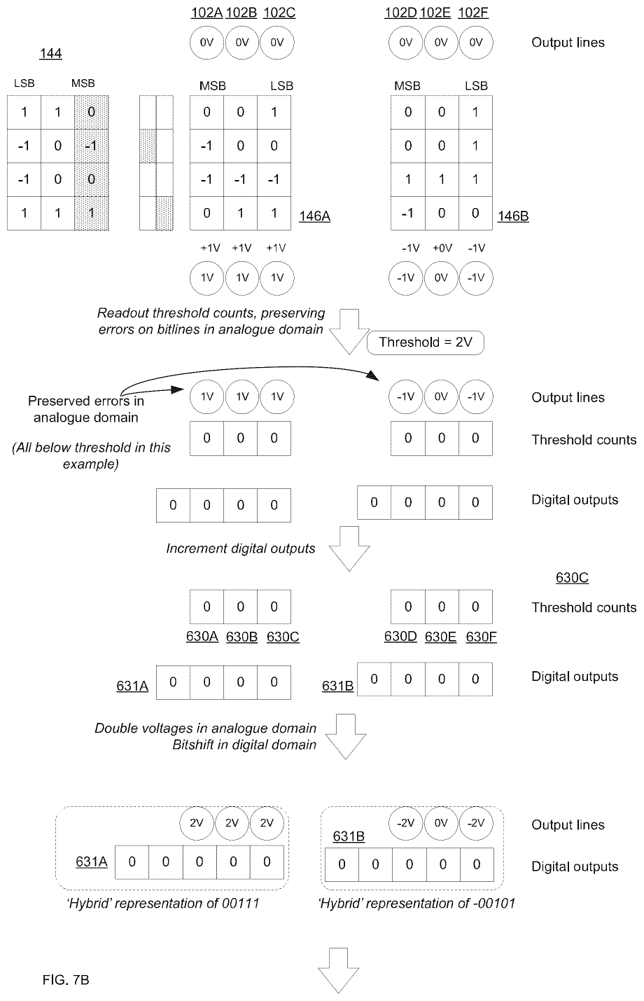

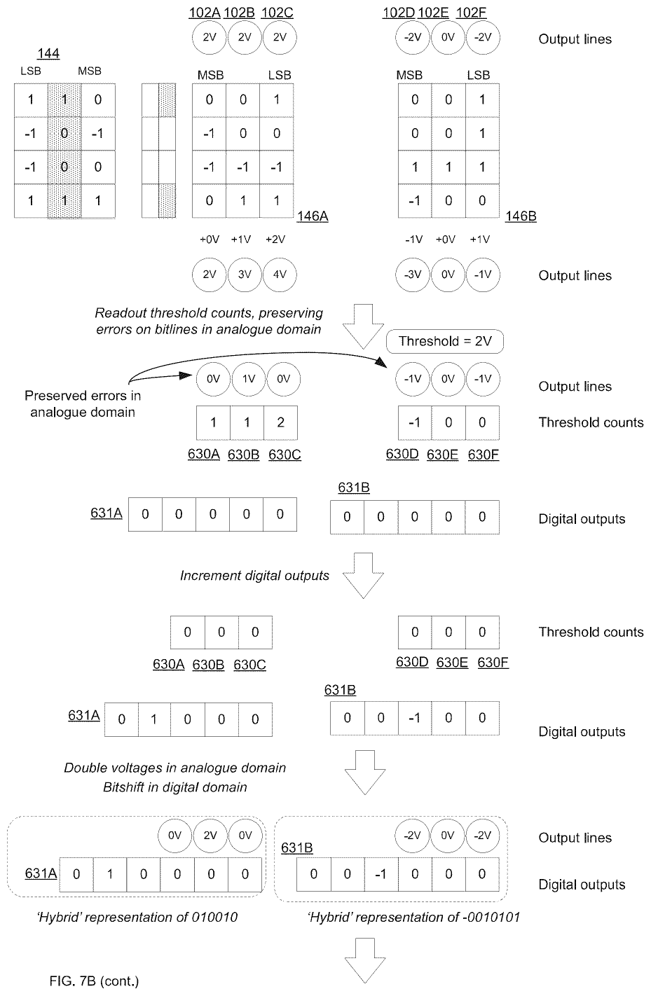

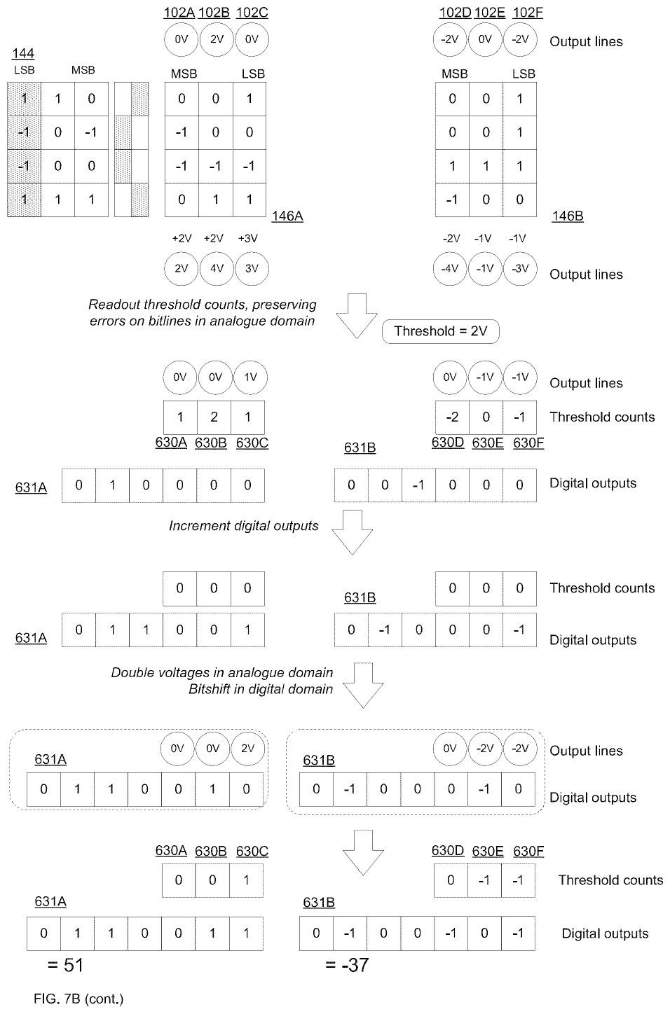

FIG. 7A shows an example implementation of the architecture of FIG. 5A based on the threshold addition/subtraction methodology of FIG. 6A applied in parallel across multiple weight digit columns, with respective digital threshold counters 600A, 600B, 600C having inputs coupled to each ADC 112A, 112B, 112C and outputs coupled to the accumulator 500. The threshold counters 600A, 600B, 600C hold the threshold counts computed in the method of FIG. 6A, which are accessed by the accumulator 500 and reset once those counts have been incorporated in an accumulated digital output 631. The parallel instances of the analog computing architecture 100 and the accumulator 500 can be implemented in circuitry within the device 620.

FIG. 7B illustrated by example an implementation of the analog to digital conversion mechanism of FIG. 5B using the threshold addition/subtraction methodology of FIG. 6A (extended to accommodate negative numbers). The operations are shown in parallel for the first weight matrix column 146A and the second weight matrix column 146B of FIG. 3B. Additional output lines 102D, 102E, 102F and threshold counters 630E, 630F, 630G are shown to accommodate the latter, forming part of additional instances of the analog computing architecture (not depicted). First and second accumulated digital outputs 631A, 631B are computed for the first and second weight columns 146A, 146B respectively. To avoid unnecessary repetition, this figure is not described in detail. As can be seen, the left-hand side of this figure mirrors the flow of FIG. 5A described above, and the right-hand side shows the equivalent flow for the second weight matrix column 146B. It is noted that the latter involves negative computations and threshold comparisons.

FIG. 7B shows various threshold count updates. Using the method of FIG. 6A, extended to negative values, and with N=2, each threshold count update can involve multiple selective subtraction/addition operations as set out above.

It is observed that the residual errors on the output lines and the accumulated digital output in each computation cycle can be thought of as a ‘hybrid’ digital-analog representation of the computation result of that cycle, as shown at various stages in FIG. 7B. It is only at the end of the process that the final result becomes fully represented in the digital domain.

As will be appreciated, there are many possible circuit implementations of the ADC control logic 628 and the accumulator 500. Appendix B provides an analysis to guide in the selection of an appropriate circuit implementation. It is generally beneficial for analog processing domain operations to be implemented in fixed-logic (non-programmable) circuitry, such as an integrated circuit. An integrated circuit may be implemented in silicone, typically in silicone layers, with its logic fixed at manufacture/fabrication. The device 620 may, for example, be embodied in a single die or chip (packaged die). In the example of FIG. 6B, it is generally beneficial to implement everything from the SM cells 202-1, . . . , 202-4 to the comparator 626 as a fixed-logic circuit, although other hardware implementations are not excluded. Multiple instances of the parallel computing architecture 100 may be implemented in a single ship or die or distributed across multiple chips/dies with a bus or other logic to facilitate communication between them.

Elements such as the cycle control logic 622, ADC control logic 628, the accumulator 500 etc. essentially operate in the digital processing domain, and may or may not be implemented in the same chip(s)/die(s) as the analog processing circuits. Whilst these can also be implemented in fixed-logic circuitry, they can equally be implemented in programmable hardware, such as a field-programmable gate array(s) or programmable processor(s) (such as a central processing unit) that executes computer-readable instructions.

As discussed, the techniques described above are not limited to any particular number format. As an alternative to trit representations, a bit representation may be used. A bit-based representation can accommodate negative numbers e.g. by representing a negative number as the difference between two positive numbers. Other number formats can be uses digits with varying relative significance weights, sometimes with some loss in precision. Certain numbers can be represented as the difference between two other numbers in such formats. With some number formats, the scale factor applied between computation cycles may be non-integer. In determining the scale factor, there are there are two factors to consider: the interpretation of states within a digit (e.g. are the states +1,0,−1 interpreted as evenly spaced), and the relative weights applied to different ‘digits’ in the input (or output) sequence. It would be straightforward to apply a non-integer weighting between separate digits, and there may be some benefit from doing so (e.g. it expands the available numeric range that can be covered with a given number of digits, although potentially with some loss in precision). When considering states within a digit, the above implementation of the +1/0/−1 cases is essentially assuming that a +1 and a −1 will cancel each other out (which is the usual case). However, there may be cases where non-uniformly-spaced states within a ‘digit’ are useful.

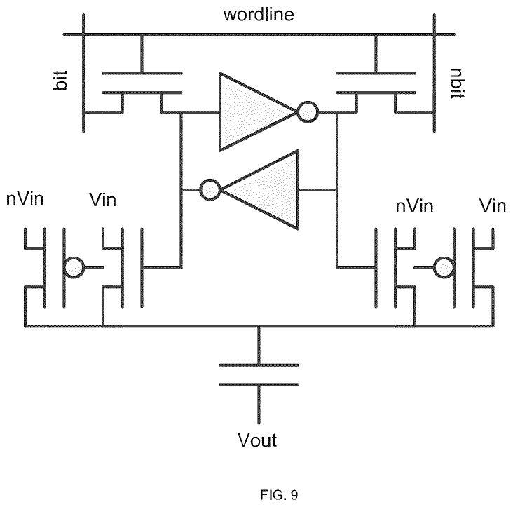

FIG. 9 shows an alternative to the SM cell 202 of FIG. 2B, which is bit-based rather than trit based. Vin and nVin connect to true and complement wordlines. A single SRAM bit cell selects one or the other for connection to Vout. The bit cell multiplies by +1, as considered before, by selecting one of Vin and nVin.

As noted, there can be any number of input lines N to accommodate vectors or any dimension. In the special case of N=1, there is a single input line on which input values (e.g. weighted input values) are received directly, with no summing of input values.

Whilst the above examples represent analog values as respective voltage deltas, this is merely one possible implementation choice, and different analog representations can be used.

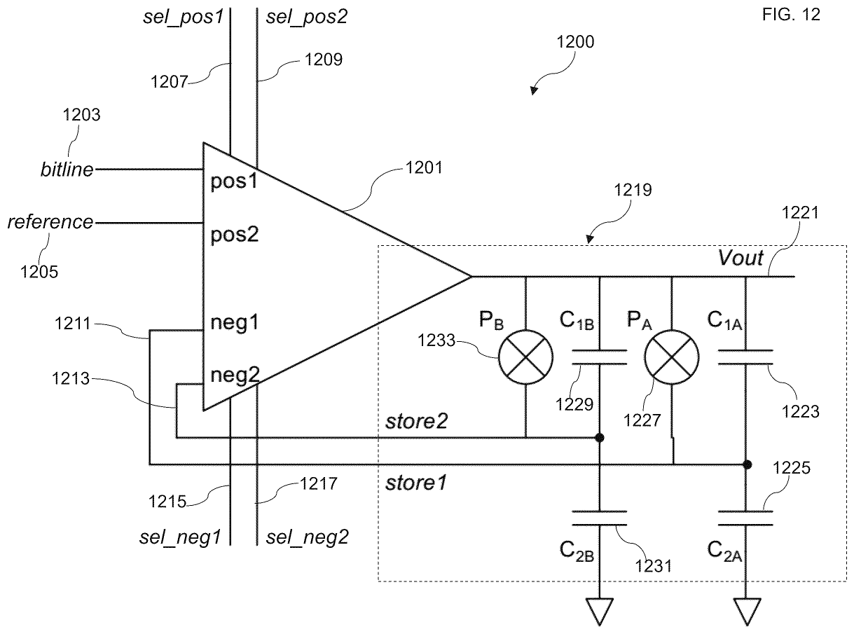

FIG. 12 shows a schematic circuit diagram for offset cancellation in an operational amplifier. The circuit shown in FIG. 12 is similar to the circuit diagram of FIG. 6E and, in some examples, may be configured in a similar way. It should be understood that the description of the configuration of the circuit diagram of FIG. 6E is also applicable to the circuit diagram of FIG. 12.

In an ideal operational amplifier, when there is an equal voltage at both the inverting and non-inverting inputs of the operational amplifier, the output voltage of the operational amplifier is zero. However, in real operational amplifiers, mismatches in the internal transistors and other components of the operational amplifiers leads to a difference in the voltage required at the inputs to produce a zero output (referred to as an ‘offset’ or ‘offset voltage’). An input offset voltage is the voltage that is applied between the operational amplifier's input terminals to force the output voltage to zero. This is typically a small direct current (DC) voltage, often measured in millivolts or microvolts. When the operational amplifier is in use, the input offset voltage is multiplied by the gain of the operational amplifier, appearing as an output voltage deviation from the ideal (or correct) value. Methods for cancelling or removing the offset voltage of the operational amplifier exist but often utilise specific circuitry for performing the cancellation which increases hardware circuit area.

A circuit 1200 comprises an operational amplifier 1201 with a first non-inverting input 1203 and a second non-inverting input 1205. In this manner, the operational amplifier has a plurality of non-inverting inputs 1203, 1205. The non-inverting inputs may be referred to as ‘positive’ inputs in some examples. In FIG. 12, the first non-inverting input 1203 is referred to as the ‘bitline’ or ‘post’. The second non-inverting input 1205 is referred to as ‘reference’ or ‘pos2’. A first select signal 1207 (referred to as ‘sel_pos1’) and a second select signal 1209 (referred to as ‘sel_pos2’) are provided as inputs to the operational amplifier 1201. When the first select signal 1207 is high, this selects the first non-inverting input 1203 as the non-inverting input (positive) for the operational amplifier 1201. When the second select signal 1209 is high, this selects the second non-inverting input 1205 as the non-inverting input (positive) for the operational amplifier 1201. In some examples, only one of the first non-inverting input 1203 and the second non-inverting input 1205 are selected at one time (i.e., one of the first select signal 1207 and the second select signal 1209 is high at the same time). In some examples, the first select signal 1207 and the second select signal 1209 are connected to the operational amplifier 1201 via an inverter.

The operational amplifier 1201 comprises a first inverting input 1211 and a second inverting input 1213. In this manner, the operational amplifier has a plurality of inverting inputs 1211, 1213. The inverting inputs may be referred to as ‘negative’ inputs in some examples. In FIG. 12, the first inverting input 1211 is referred to as ‘neg1’. The second inverting input 1213 is referred to as ‘neg2’. A third select signal 1215 (referred to as ‘sel_neg1’) and a fourth select signal 1217 (referred to as ‘sel_neg2’) are provided as inputs to the operational amplifier 1201. When the third select signal 1215 is high, this selects the first inverting input 1211 as the inverting input (negative) for the operational amplifier 1201. When the fourth select signal 1217 is high, this selects the second inverting input 1213 as the inverting input (negative) for the operational amplifier 1201. In some examples, only one of the first inverting input 1211 and the second inverting input 1213 are selected at one time (i.e., one of the third select signal 1215 and the fourth select signal 1217 is high at the same time). In some examples, the third select signal 1215 and the fourth select signal 1217 are connected to the operational amplifier 1201 via an inverter.

As the operational amplifier 1201 comprises a plurality of switched non-inverting inputs and switched inverting inputs, the operational amplifier 1201 may be referred to as a combined multiplexor (mux) and operational amplifier (combined mux and OpAmp).

A feedback circuit 1219 is arranged between an output 1221 (Vout) of the operational amplifier 1201 and the inverting inputs 1211, 1213. The feedback circuit 1219 comprises a first sub-circuit arranged between the output 1221 and the first inverting input 1211 (neg1). The first sub-circuit comprises a first capacitor 1223 (C1A) and a second capacitor 1225 (C2A) arranged in series. The second capacitor 1225 is also connected to ground. A first pass gate (switch) 1227 of the first sub-circuit is connected in parallel with the first capacitor 1223, such that the first pass gate 1227 short-circuits the first capacitor 1223 when the first pass gate 1227 is closed. The first sub-circuit is referred to as ‘store1’ in some examples, as a first voltage may be stored by at least one of the capacitors of the first sub-circuit. The feedback circuit 1219 further comprises a second sub-circuit arranged between the output 1221 and the second inverting input 1213 (neg2). The second sub-circuit comprises a third capacitor 1229 (C1B) and a fourth capacitor 1231 (C2B) arranged in series. The fourth capacitor 1231 is also connected to ground. A second pass gate (switch) 1233 of the second sub-circuit is connected in parallel with the third capacitor 1229, such that the second pass gate 1233 short-circuits the third capacitor 1229 when the second pass gate 1233 is closed. The second sub-circuit is referred to as ‘store2’ in some examples, as a second voltage may be stored by at least one of the capacitors of the second sub-circuit.

The first capacitor 1223 and the second capacitor 1225 are arranged as a capacitive voltage divider in the first sub-circuit, wherein the divider is connected to the first inverting input 1211 (neg1) of the operational amplifier 1201. The third capacitor 1229 and the fourth capacitor 1231 are arranged as a capacitive voltage divider in the second sub-circuit, wherein the divider is connected to the second inverting input 1213 (neg2) of the operational amplifier 1201. The capacitors 1223, 1225, 1229, 1231 are arranged in the feedback circuit 1219 to be used for voltage storage (e.g., to store a value) and for input offset cancellation. The voltage storage and input offset cancellation is achieved in conjunction with the first 1227 and second pass gates 1233. Control circuitry (not shown) is arranged to control the opening and the closing of the first 1227 and second pass gates 1233 This will be described in more detail below.

In some examples, the capacitance of the first capacitor 1223 and the capacitance of the third capacitor 1229 is substantially the same (e.g., first capacitor 1223 and third capacitor 1229=capacitance 1 (C1)). In some examples, the capacitance of the second capacitor 1225 and the capacitance of the fourth capacitor 1231 is substantially the same (e.g., second capacitor 1225 and fourth capacitor 1231=C2). In other examples, at least some of the capacitances of the capacitors 1223, 1225, 1229, 1231 are different. When assuming that the first capacitor 1223 and third capacitor 1229=C1, and the second capacitor 1225 and fourth capacitor 1231=C2, then C2/C1 sets the gain of the operational amplifier 1201.

In some examples, the circuit 1200 is configured to generate an output that is proportional to the difference between two input voltages (e.g., input A and input B). Input A and input B may be stored values (represented as voltages) (not shown in FIG. 12). In this manner, the circuit is able to determine the difference between the two inputs. This is useful in many computing applications, such as for examples in artificial intelligence (AI) and machine learning (ML) model training and inference.

As described above, an input offset voltage associated with the operational amplifier 1201 may cause a determination of a difference between two inputs to be inaccurate. In this manner, the value of the voltage offset should be taken into account when determining the difference.

$${V}_{out} = A ( {V}_{+} - {V}_{-} - {V}_{offset} )$$

$${V}_{-} = {V}_{out}$$

$${V}_{out} = A ( {V}_{+} - {V}_{out} - {V}_{offset} )$$

$${V}_{out} ( 1 + A ) = A ( {V}_{+} - {V}_{offset} )$$

$${V}_{out} = \frac{A}{1 + A} ( {V}_{+} + {V}_{offset} ) = \frac{1}{( 1 + \frac{1}{A} ) ( {V}_{+} - {V}_{offset} )} \approx ( 1 - \frac{1}{A} ) ( {V}_{+} - {V}_{offset} ) = {V}_{+} - \frac{{V}_{-}}{A} - ( 1 - \frac{1}{A} ) {V}_{offset}$$

In this manner, the stored value differs from the input value by the amount:

$$- \frac{{V}_{-}}{A} - ( 1 - \frac{1}{A} ) {V}_{offset}$$

When, for example, A=1000, then the V_{offset} term in the equation may be considered the most significant. Due to this, the voltage offset (V_{offset}) often influences the output from the operational amplifier (i.e., negatively skews the result of the determination).

In the presence on gain (of the operational amplifier 1201), the output voltage may be represented as follows:

$${V}_{out} = A ( {V}_{+} - {V}_{-} - {V}_{offset} )$$

$${V}_{-} = \frac{1}{α} {V}_{out}$$

$${V}_{out} = A ( {V}_{+} - \frac{1}{α} {V}_{out} - {V}_{offset} )$$

$${V}_{out} ( 1 + \frac{A}{α} ) = A ( {V}_{+} - {V}_{offset} )$$

$${V}_{out} = ( \frac{A}{1 + \frac{A}{α}} ) ( {V}_{+} - {V}_{offset} ) \approx α ( {V}_{+} - {V}_{offset} )$$

The voltage offset of the operational amplifier 1201 may be dependent on different transistors that are involved at the input when the bitline 1203 or the reference 1205 is connected to the non-inverting input, for the two different inputs A and B. Therefore, the following notation is used for the voltage offset (where appropriate):

$${V}_{offset} = {V}_{bl , A}$$

$${V}_{offset} = {V}_{bl , B}$$

$${V}_{offset} = {V}_{ref , A}$$

$${V}_{offset} = {V}_{ref , B}$$

In some examples, the circuit 1200 operates in phases to determine the difference between two input values A, B (or two input voltages A, B). The two inputs may be sequentially provided on one of the non-inverting inputs (e.g., the bitline 1203). Alternatively, one of the inputs may be provided on the bitline 1203 and the other of the two inputs on the reference 1205. In the following example, the two inputs A, B are provided on the bitline 1203 (at different times). This is described in more detail below.

At P1, sel_pos1 1207 is high and sel_pos2 1209 is low which means that bitline 1203 is connected to the non-inverting input of the operational amplifier 1201. At P1, the voltage of bitline 1203 equals input A (e.g., a voltage associated with input A). Sel_neg1 1205 is high and sel_neg2 is low, which means that neg1 is connected to the inverting input (i.e., connected to the first sub-circuit, ‘store1’). The control circuitry controls the first pass gate 1227 to be closed (on) and the second pass gate 1233 to be open (off). With this configuration, the operational amplifier 1201 functions as a unity-gain buffer (or voltage follower). The voltage of the output 1221 is equal to bitline 1203 minus the voltage offset. The voltage of the output 1221 is also equal to store1 (Vout=bitline−V_{bl,A}=store1). The first pass gate 1227 is then opened (switched off), resulting in the second capacitor 1225 storing the voltage (Vout, store1).

At P2, sel_pos1 1207 is high and sel_pos2 1209 is low, such that bitline 1203 remains connected to the non-inverting input of the operational amplifier 1201. At P2, the voltage of bitline 1203 is switched to input B (e.g., a voltage associated with input B). Sel_neg1 1205 is low and sel_neg2 is high, which means that neg2 is connected to the inverting input (i.e., connected to the second sub-circuit, ‘store2’). The control circuitry controls the first pass gate 1227 to be open (off) and the second pass gate 1233 to be closed (on). With this configuration, the operational amplifier 1201 functions as a unity-gain buffer (or voltage follower). The voltage of the output 1221 is equal to bitline 1203 minus the offset voltage. The voltage of the output 1221 is also equal to store2 (Vout=bitline−V_{bl,B}=store2). The second pass gate 1233 is then opened (switched off), resulting in the fourth capacitor 1231 storing the voltage (Vout, store2). The voltage stored on the second capacitor 1225 is shifted by the change in Vout (assuming that the voltages of input A and input B are different) since the first pass gate 1227 was opened (switched off). The stored voltages in store1 and store 2 includes the (unwanted) offset voltage associated with the operational amplifier 1201. Following P2, the voltage delta in store1 (the second capacitor 1225) is as follows, wherein the first 1223 and the third capacitor 1229 have capacitance C1 and the second 1225 and fourth capacitor 1231 have capacitance C2, and wherein a is the gain of the operational amplifier:

$$Δ store 1 = \frac{1}{{α}_{A}} ΔV out \frac{1}{{α}_{A}} ( store 2 - store 1 ) = 1 / {α}_{A} ( ( {bitline}_{B} - {V}_{bl , B} ) - ( {bitline}_{A} - {V}_{bl , A} ) )$$

$$Δ store 1 = \frac{1}{{α}_{A}} ( {bitline}_{B} - {bitline}_{A} - {V}_{bl , B} + {V}_{bl , A} )$$

$$\frac{1}{{α}_{A}} = \frac{{C}_{1 A}}{{C}_{1 A} + {C}_{2 A}}$$

$$store 1 = {bitline}_{A} + \frac{1}{{α}_{A}} ( {bitline}_{B} - {bitline}_{A} ) - {V}_{bl , B} - \frac{1}{{α}_{A}} ( {V}_{bl , B} - {V}_{bl , A} )$$

At P3, sel_pos1 1207 is low and sel_pos2 1209 is high, such that reference 1205 is connected to the non-inverting input of the operational amplifier 1201. Sel_neg1 1205 is low and sel_neg2 is high, which means that neg2 is connected to the inverting input (i.e., connected to the second sub-circuit, ‘store2’). The control circuitry controls the first pass gate 1227 to be open (off) and the second pass gate 1233 to be open (off). With this configuration, the operational amplifier 1201 functions as feedback amplifier with gain

$${α}_{B} = \frac{{C}_{1 B} + {C}_{2 B}}{{C}_{1 B}} .$$

This change in the circuit configuration means that Vout shifts so that ΔVᵢₙ=−V_{ref,B}, Stated differently, neg2→reference−V_{ref,B}.

$$Δ store 2 = reference - {V}_{ref , B} - ( {bitline}_{B} - {V}_{bl , B} ) = ( reference - {bitline}_{B} ) - ( {V}_{ref , B} - {V}_{bl , B} )$$

$$Δ V out = {α}_{B} Δ store 2 = {α}_{B} ( reference - {bitline}_{B} ) - {α}_{B} ( {V}_{ref , B} - {V}_{bl , B} )$$

$$Δ store 1 = V out / {α}_{A}$$

$$store 1 \to {bitline}_{A} + \frac{1}{{α}_{A}} ( {bitline}_{B} - {bitline}_{A} ) - {V}_{bl , A} - \frac{1}{{α}_{A}} ( {V}_{bl , B} - {V}_{bl , A} ) + \frac{{α}_{B}}{{α}_{A}} ( reference - {bitline}_{B} ) - \frac{{α}_{B}}{{α}_{A}} ( {V}_{ref , B} - {V}_{bl , B} )$$

$$store 1 = {bitline}_{A} ( 1 - \frac{1}{{α}_{A}} ) - {bitline}_{B} ( \frac{{α}_{B}}{{α}_{A}} - \frac{1}{{α}_{A}} ) + ( \frac{{α}_{B}}{{α}_{A}} ) reference - {V}_{bl , A} - \frac{1}{{α}_{A}} ( {V}_{bl , B} - {V}_{bl , A} ) - \frac{{α}_{B}}{{α}_{A}} ( {V}_{ref , B} - {V}_{bl , B} )$$

At P4, sel_pos1 1207 is low and sel_pos2 1209 is high, such that reference 1205 is connected to the non-inverting input of the operational amplifier 1201. Sel_neg1 1205 is high and sel_neg2 is low, which means that neg1 is connected to the inverting input (i.e., connected to the first sub-circuit, ‘store1’). The control circuitry controls the first pass gate 1227 to be open (off) and the second pass gate 1233 to be open (off). With this configuration, the operational amplifier 1201 functions as feedback amplifier with gain

$${α}_{A} = \frac{{C}_{1 A} + {C}_{2 A}}{{C}_{1 A}} .$$

This change in the circuit configuration means that Vout shifts so that ΔVᵢₙ=−V_{ref,A}, Stated differently, neg1→reference−V_{ref,A}.

$$Δ store 1 = reference - {V}_{ref , A} - ( {bitline}_{A} ( 1 - \frac{1}{{α}_{A}} ) - {bitline}_{B} ( \frac{{α}_{B}}{{α}_{A}} - \frac{1}{{α}_{A}} ) + ( \frac{{α}_{B}}{{α}_{A}} ) reference - {V}_{bl , A} - \frac{1}{{α}_{A}} ( {V}_{bl , B} - {V}_{bl , A} ) - \frac{{α}_{B}}{{α}_{A}} ( {V}_{ref , B} - {V}_{bl , B} ) )$$

$$Δ store 1 = reference ( 1 - ( \frac{{α}_{B}}{{α}_{A}} ) ) + {bitline}_{B} ( \frac{{α}_{B}}{{α}_{A}} - \frac{1}{{α}_{A}} ) - {bitline}_{A} ( 1 - \frac{1}{{α}_{A}} ) + ( {V}_{bl , A} - {V}_{ref , A} ) + \frac{1}{{α}_{A}} ( {V}_{bl , B} - {V}_{bl , A} ) + \frac{{α}_{B}}{{α}_{A}} ( {V}_{ref , B} - {V}_{bl , B} )$$

$$Δ V out = {α}_{A} Δ store 1$$

$$Δ V out = reference ( {α}_{A} - {α}_{B} ) + {bitline}_{B} ( {α}_{B} - 1 ) - {bitline}_{A} ( {α}_{A} - 1 ) + {α}_{A} ( {V}_{bl , A} - {V}_{ref , A} ) + ( {V}_{bl , B} - {V}_{bl , A} ) + {α}_{B} ( {V}_{ref , B} - {V}_{bl , B} )$$

$$Δ V out = reference ( {β}_{A} - {β}_{B} ) + {bitline}_{B} ( {β}_{B} ) - {bitline}_{A} ( {β}_{A} ) + {α}_{A} ( {V}_{bl , A} - {V}_{ref , A} ) + ( {V}_{bl , B} - {V}_{bl , A} ) + {α}_{B} ( {V}_{ref , B} - {V}_{bl , B} )$$

The voltage offset term in the above equation is:

$${α}_{A} ( {V}_{bl , A} - {V}_{ref , A} ) + ( {V}_{bl , B} - {V}_{bl , A} ) + {α}_{B} ( {V}_{ref , B} - {V}_{bl , B} )$$

$$β = ( \frac{{C}_{2}}{{C}_{1}} ) = α - 1 ( {α}_{A} - 1 ) {V}_{bl , A} - {α}_{A} {V}_{ref , A} + {α}_{B} {V}_{ref , B} - ( {α}_{B} - 1 ) {V}_{bl , B} = {β}_{A} {V}_{bl , A} - {α}_{A} {V}_{ref , A} + {α}_{B} {V}_{ref , B} - {β}_{B} {V}_{bl , B} ( {β}_{A} {V}_{bl , A} - {β}_{B} {V}_{bl , B} ) + ( {α}_{B} {V}_{ref , B} - {α}_{A} {V}_{ref , A} )$$

The voltage offset term above therefore indicates that the offset can be cancelled out.

The circuit 1200 has the advantage that the voltage output 1221 is indicative (e.g., proportional) to a difference between two input values (e.g., stored input voltages), which takes into account the input offset voltage(s) of the operational amplifier 1201. Due to the arrangement of the circuit 1200, the offset is cancelled/removed without requiring additional circuitry for performing the cancellation. The same circuitry (e.g., the feedback circuit 1219) is used for both value storage and determination as well as for the offset cancellation. This means that hardware circuit area usage is more efficient when compared to other systems which have dedicated circuitry for cancelling the offset.

Due to the capacitive voltage divider effect of the first and second sub-circuits, this caused a ‘disturbance’ in the previous phase (or cycle), as described above. The first pass gate 1227 and the second pass gate 1233 being open or closed means that the capacitors will store either the ‘full’ voltage, or the ‘divided’ voltage. This means that in the following phase (e.g., 2^{nd} phase), the relevant capacitor stores the voltage difference plus the ‘disturbance’. Then, once the four phases have completed, the accurate voltage difference has been determined with the offset fully cancelled out.

In the example described above in P1 to P4, the two input values A,B are provided on the bitline 1203. In other examples, P1 and P4 are modified accordingly such that input A is provided on the bitline 1203 at a point in time, and then input B is provided on the reference 1205 at a later point in time. In this manner, the circuit 1200 determines the voltage difference between the bitline 1203 and the reference 1205.

### APPENDIX A

The principles of capacitive summing are explained in detail with reference to FIGS. 12A-D.

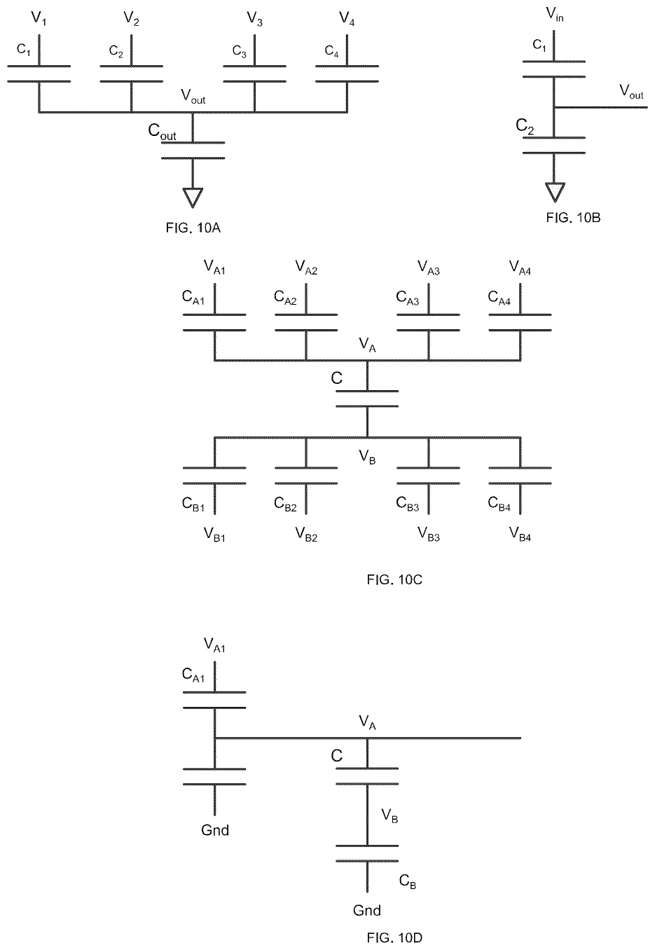

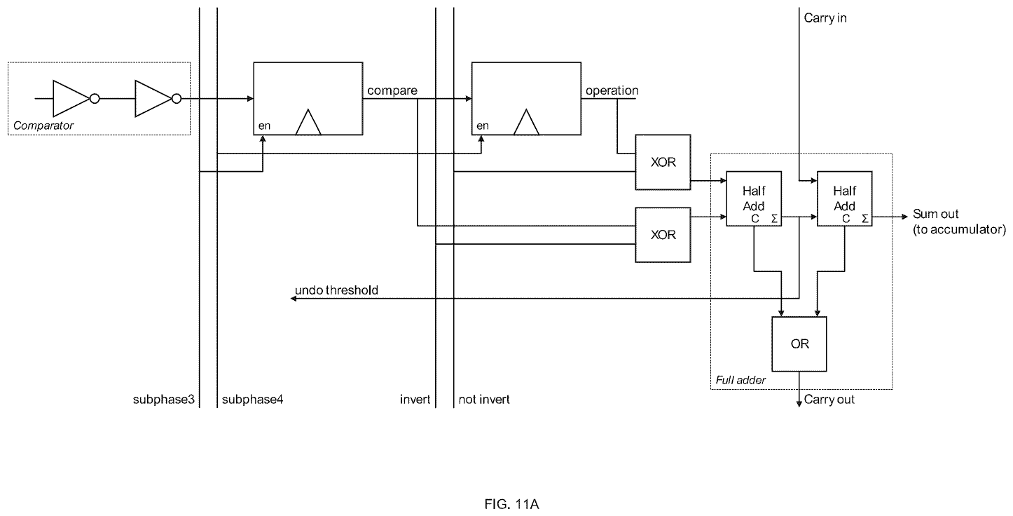

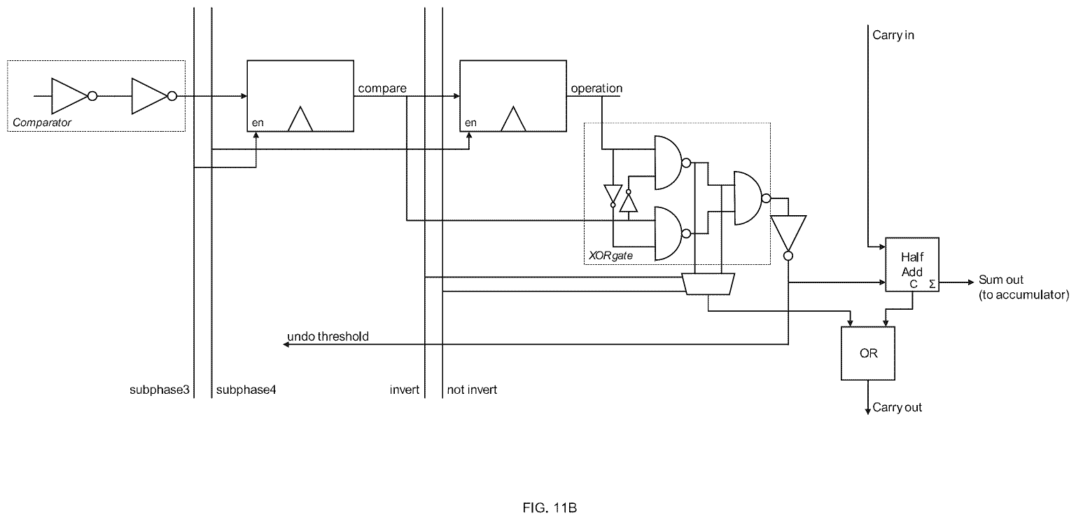

### FIG. 10A—Operation of Basic Capacitive Sum Circuit

$${I}_{i} = {C}_{i} \frac{d ( {V}_{i} - {V}_{out} )}{dt} = {C}_{i} ( \frac{{d V}_{i}}{dt} - \frac{{d V}_{out}}{dt} )$$

$${I}_{out} = {C}_{out} \frac{{d V}_{out}}{dt} = {\sum }_{i} {I}_{i}$$

$${C}_{out} \frac{{d V}_{out}}{dt} = {\sum }_{i} {C}_{i} ( \frac{{d V}_{i}}{dt} - \frac{{d V}_{out}}{dt} )$$

$$( {C}_{out} + {\sum }_{i} {C}_{i} ) \frac{{d V}_{out}}{dt} = {\sum }_{i} {C}_{i} \frac{{d V}_{i}}{dt}$$

$$\int ( {C}_{out} + {\sum }_{i} {C}_{i} ) \frac{{d V}_{out}}{dt} dt = \int {\sum }_{i} {C}_{i} \frac{{d V}_{i}}{dt} dt = {\sum }_{i} {C}_{i} \int \frac{{d V}_{i}}{dt} dt$$

$$( {C}_{out} + {\sum }_{i} {C}_{i} ) {Δ V}_{out} = {\sum }_{i} {C}_{i} {Δ V}_{i}$$

If the Cᵢ are all equal then this becomes:

$$( {C}_{out} + {NC}_{in} ) {Δ V}_{out} = {C}_{in} {\sum }_{i} {Δ V}_{i}$$

$${Δ V}_{out} = \frac{{C}_{in}}{{C}_{out} + {NC}_{in}} {\sum }_{i} {Δ V}_{i}$$

$${Δ V}_{out} = ( \frac{1}{\frac{{NC}_{out}}{{C}_{in}} + N} ) {\sum }_{i} {Δ V}_{i}$$

In other words, a change in output voltage is proportional to the sum of the changes in input voltage, and for small Cₒᵤₜ relative to Cᵢₙ, the output is the average of the inputs.

### FIG. 10B—Capacitive Divider

If this was a resistor circuit, the following would hold:

$$\frac{{V}_{out}}{{V}_{in}} = \frac{{R}_{2}}{{R}_{1} + {R}_{2}}$$

However, capacitors behave like impedances of value 1/C, so this becomes:

$$\frac{{V}_{out}}{{V}_{in}} = \frac{\frac{1}{{C}_{2}}}{\frac{1}{{C}_{1}} + \frac{1}{{C}_{2}}} = \frac{\frac{1}{{C}_{2}}}{( \frac{{C}_{1} + {C}_{2}}{{C}_{1} {C}_{2}} )} = \frac{{C}_{1}}{{C}_{1} + {C}_{2}}$$

Whilst this looks superficially like the resistor equation, the numerator is now the component at the top of the stack, not the one at the bottom (i.e. the one connected to the input, not the one connected to ground).

This formula can be used to help analyse more complex capacitor networks

### FIGS. 10C-D—Full Capacitive Summing

The upper circuit can be analysed by treating it as a linear circuit, working out the dependence of ΔV_{A} and ΔV_{B} on each individual input, and then summing the results to get the dependence on all inputs together.

The upper circuit then reduces to the lower one when analysing a single input, with the following definitions:

$${C}_{A} = {\sum }_{i} {C}_{Ai}$$

$${C}_{B} = {\sum }_{j} {C}_{Bj}$$

The right-hand branch from V_{A} to Gnd has equivalent capacitance given by the series capacitor formula:

$$\frac{1}{{C}_{equiv}} = \frac{1}{C} + \frac{1}{{C}_{B}}$$

$${C}_{equiv} = \frac{{CC}_{B}}{C + {C}_{B}}$$

Therefore, the total capacitance from V_{A} to ground is:

$$( {C}_{A} - {C}_{A 1} ) + \frac{{CC}_{B}}{C + {C}_{B}}$$

$$So :$$

$$\frac{{V}_{A}}{{V}_{A 1}} = \frac{{C}_{A 1}}{{C}_{A 1} + ( {C}_{A} - {C}_{A 1} ) + \frac{{CC}_{B}}{C + {C}_{B}}} = \frac{{C}_{A 1}}{{C}_{A} + \frac{{CC}_{B}}{C + {C}_{B}}} = \frac{{C}_{A 1} ( C + {C}_{B} )}{{CC}_{A} + {CC}_{B} + {C}_{A} {C}_{B}}$$

C and C_{B} also act as a potential divider between V_{A} and V_{B}, so:

$$\frac{{V}_{B}}{{V}_{A}} = \frac{C}{C + {C}_{B}}$$

$$And :$$

$$\frac{{V}_{B}}{{V}_{A 1}} = ( \frac{C}{C + {C}_{B}} ) ( \frac{{C}_{A 1} ( C + {C}_{B} )}{{CC}_{A} + {CC}_{B} + {C}_{A} {C}_{B}} ) = \frac{{C}_{A 1} C}{{CC}_{A} + {CC}_{B} + {C}_{A} {C}_{B}}$$

Overall therefore:

$${Δ V}_{B} = ( \frac{1}{{CC}_{A} + {CC}_{B} + {C}_{A} {C}_{B}} ) ( C {\sum }_{i} {C}_{Ai} {V}_{Ai} + ( C + {C}_{A} ) {\sum }_{j} {C}_{Bj} {V}_{Bj} )$$

In other words, introducing the capacitor C that splits a capacitive sum network into two subsections introduces a relative weighting of the impact of the two subsections on the overall output.

In the context of the described analog computing architecture, where C_{Ai} are the input capacitors, and C_{Bj} the feedback network, a fixed relationship between the capacitances in the two networks will ensure correct operation (i.e. the ability to feed back with the correct relative weighting). Introducing the extra capacitor means that the C_{Bj} can be smaller while still having the same relative impact on the output.

### APPENDIX B

### Bit-Level Control Logic

The following table was created by creating a behavioral model of the circuit of FIG. 6C (operating as described above with multiple phases and sub-phases), feeding it with multiple input voltages and recording the states of various input and output signals. The logic to create the required relationships between the signals can be inferred from this table.

Italics are outputs of the control logic, non-italic are inputs\

| | Compare | Real | Accum. | Next real | Undo |
|---|---|---|---|---|---|
| Inverted | output | operation | update | operation | threshold |
| 0 | 0 | ADD | −1 | SUB | 0 |
| 0 | 0 | SUB | 0 | SUB | 1 |
| 0 | 1 | ADD | 0 | ADD | 1 |
| 0 | 1 | SUB | 1 | ADD | 0 |
| 1 | 0 | ADD | 1 | SUB | 0 |
| 1 | 0 | SUB | 0 | SUB | 1 |
| 1 | 1 | ADD | 0 | ADD | 1 |
| 1 | 1 | SUB | −1 | ADD | 0 |

### Key:

Real operation=effective operation, modified by whether or not it's an inverted cycle. i.e. an inverted add becomes a real subtract. The real operations are more useful to know about than the “behavioural” operations (i.e. without tracking the inversions)
Undo threshold=should the threshold be put back in sub-phase 4 since the threshold was not exceeded.
Accumulator update=value to be added to the accumulator

The ‘next real operation’ output column is equal to the ‘compare output’ column (especially if the encoding is SUB=0, ADD=1). In the following, the accumulator update is split into add 1 and add−1 columns:

| | | | | | | Undo |
|---|---|---|---|---|---|---|
| In- | Compare | Real | | | Next real | thresh- |
| verted | output | operation | Add 1 | Add −1 | operation | old |
| 0 | 0 | ADD | 0 | 1 | SUB | 0 |
| 0 | 0 | SUB | 0 | 0 | SUB | 1 |
| 0 | 1 | ADD | 0 | 0 | ADD | 1 |
| 0 | 1 | SUB | 1 | 0 | ADD | 0 |
| 1 | 0 | ADD | 1 | 0 | SUB | 0 |
| 1 | 0 | SUB | 0 | 0 | SUB | 1 |
| 1 | 1 | ADD | 0 | 0 | ADD | 1 |
| 1 | 1 | SUB | 0 | 1 | ADD | 0 |

The ‘add 1, add−1’=(0,0) can be replaced with (1,1) (i.e. both add and subtract, giving a net no change), which allows a simplification of the logic (changes are marked in red). This results in the following logic:
Add 1=XOR(inverted, compare output).
Add−1=XOR(inverted, real operation).
Undo threshold=NXOR(real operation, compare output)

This means the the per-bit control logic could be implemented as 3 XOR gates (plus registers).

| | | | | | | Undo |
|---|---|---|---|---|---|---|
| In- | Compare | Real | | | Next real | thresh- |
| verted | output | operation | Add 1 | Add −1 | operation | old |
| 0 | 0 | ADD | 0 | 1 | SUB | 0 |
| 0 | 0 | SUB | 0 | 0 | SUB | 1 |
| 0 | 1 | ADD | 1 | 1 | ADD | 1 |
| 0 | 1 | SUB | 1 | 0 | ADD | 0 |
| 1 | 0 | ADD | 1 | 0 | SUB | 0 |
| 1 | 0 | SUB | 1 | 1 | SUB | 1 |
| 1 | 1 | ADD | 0 | 0 | ADD | 1 |
| 1 | 1 | SUB | 0 | 1 | ADD | 0 |

### Integration with the Accumulator

The ‘add 1’ and ‘add−1’ signals are concatenated across multiple columns, to create a “positive update” and a “negative update” word for the accumulator. The negative update is subtracted from the positive update to give the net update for the accumulator:

Subtraction is implemented as bitwise inversion followed by adding 1.

This can be implemented as a 1-bit full adder cell per bit column, with carry propagation between bit columns in a weight column, and Cᵢₙ to the LSB=1

### Further Optimisation

The first stage of the full adder cell performs the XOR of its 2 inputs:
XOR(add 1, NOT(add−1))=XOR(XOR(inv, compare), NXOR(inv, real op))
XOR(add 1, NOT(add−1))=XOR(XOR(inv, compare), XOR(NOT(inv), real op)).
XOR(add 1, NOT(add−1))=XOR(XOR(real op, compare), XOR(NOT(inv), inv))
XOR(add 1, NOT(add−1))=XOR(XOR(real op, compare), 1)
XOR(add 1, NOT(add−1))=NXOR(real op, compare)=Undo

### Threshold

In other words, this initial stage of the full adder cell can be replaced with the same signal that is used for the undo threshold signal (although the carry control signals will still need to be generated).

Alternatively the Undo Threshold signal can be taken from the sum output of a half-adder that combines the other two signals.

### Half-Adder Implementation

An implementation that uses a compact half-adder is shown in FIG. 11A.

This implementation assumes global control signals (subphase1, subphase2, subphase3, subphase4) to indicate the current subphase.

Comparator output (i.e. buffered version of bitline signal) is captured in subphase3. ‘Next operation’ is derived from comparator output, and updates in subphase4 Invert and not invert are also global control signals.

Implementations of the XOR function can use both true and complement versions of their inputs, so routing both true and complement makes sense.

### Alternative Implementation with Single XOR and Separate Carry Generation

As noted above, the sum path of the first half adder cell is equivalent to the undo threshold signal: NXOR(real op, compare). The carry output of the first half-adder cell is the AND of the two inputs:
C=AND(XOR(inv, compare), NXOR(inv, real op))
C=AND(XOR(inv, compare), XOR(NOT(inv), real op)).
C=(i̅n̅v̅.compare|c̅o̅m̅p̅a̅r̅e̅.inv).(i̅n̅v̅.r̅e̅a̅l̅ o̅p̅|inv.real op)
C=i̅n̅v̅.compare.r̅e̅a̅l̅ o̅p̅|inv.c̅o̅m̅p̅a̅r̅e̅.real op

This last equation can be interpreted as a mux (controlled by the invert signal) that selects between compare.r̅e̅a̅l̅ o̅p̅ and c̅o̅m̅p̅a̅r̅e̅.real op.

These two terms are intermediates in XOR(compare, real op), i.e. not (Undo Threshold), so that the 2 XORs and 2 half-adders in the previous circuit can be replaced with a single XOR (implemented as an AND-OR, or NAND-NAND tree), a mux, and a single half-adder.

An alternative implementation based on this analysis is shown in FIG. 11B.

### Control Circuit

A similar approach can be used to determine the control circuit needed for the threshold input to the analog sum (this is a digital signal, capacitively coupled to the analog sum node).

For an ADD operation, threshold is low during pre-charge, and high in sub-phase 3. For a SUB operation, threshold is high during pre-charge, and low in sub-phase 3.

| Sub- | Sub- | Sub- | Sub- | | | |
|---|---|---|---|---|---|---|
| phase | phase | phase | phase | Undo | Real | |
| 1 | 2 | 3 | 4 | Threshold | operation | Threshold |
| One high, one low | | 0 | 0 | X | ADD | 0 |
| (i.e. pre-charge) | | 0 | 0 | X | SUB | 1 |
| 0 | 0 | 1 | 0 | X | ADD | 1 |
| 0 | 0 | 1 | 0 | X | SUB | 0 |
| 0 | 0 | 0 | 1 | 0 | ADD | 1 |
| 0 | 0 | 0 | 1 | 0 | SUB | 0 |
| 0 | 0 | 0 | 1 | 1 | ADD | 0 |
| 0 | 0 | 0 | 1 | 1 | SUB | 1 |

### Key

Real operation=effective operation, modified by whether or not it's an inverted cycle. i.e. an inverted add becomes a real subtract. The real operations are more useful to know about than the “behavioural” operations (i.e. without tracking the inversions)
Undo threshold=should the threshold be put back in sub-phase 4 since the threshold was not exceeded.
Threshold=value to be capacitively coupled into the analog sum

$$Real operation encoding - ADD = 0 , SUB = 1$$

‘Threshold’ can be generated with an XOR gate:
One input is the operation
The other input is (subphase3 OR (subphase 4 AND Real operation))

| Sub- | Sub- | Sub- | Sub- | | | |
|---|---|---|---|---|---|---|
| phase | phase | phase | phase | Undo | Real | |
| 1 | 2 | 3 | 4 | Threshold | operation | Threshold |
| One high, one low | | 0 | 0 | X | ADD | 0 |
| (i.e. pre-charge) | | 0 | 0 | X | SUB | 1 |
| 0 | 0 | 1 | 0 | X | ADD | 1 |
| 0 | 0 | 1 | 0 | X | SUB | 0 |
| 0 | 0 | 0 | 1 | 0 | ADD | 1 |
| 0 | 0 | 0 | 1 | 0 | SUB | 0 |
| 0 | 0 | 0 | 1 | 1 | ADD | 0 |
| 0 | 0 | 0 | 1 | 1 | SUB | 1 |

### Key

Real operation=effective operation, modified by whether or not it's an inverted cycle. i.e. an inverted add becomes a real subtract. The real operations are more useful to know about than the “behavioral” operations (i.e. without tracking the inversions)
Undo threshold=should the threshold be put back in sub-phase 4 since the threshold was not exceeded.
Threshold=value to be capacitively coupled into the analog sum

$$Real operation encoding - ADD = 0 , SUB = 1$$

1. A method of transforming a sequence of analog inputs into a quantized digital outputs, the method comprising:
receiving in an analog processing domain a first analog input of the sequence;
generating in the analog processing domain, based on the first analog input, a first analog output;
quantizing the first analog output, resulting in:
(i) a first quantized digital output, and
(ii) a first analog residual error;
scaling in the analog processing domain the first analog residual error, resulting in a first analog scaled residual error;
receiving in the analog processing domain a second analog input of the input sequence;
generating in the analog processing domain, based on the second analog input and the first scaled analog residual error, a second analog output; and
quantizing the second analog output, resulting in a second quantized digital output.

2. The method of claim 1, comprising accumulating in a digital processing domain the first digital output with the second digital output, resulting in an accumulated digital output.

3. The method of claim 1, wherein quantizing the second analog output additionally results in a second analog residual error, and the method comprises:
scaling in the analog processing domain the second analog residual error, resulting in a second analog scaled residual error;
receiving in the analog processing domain a third analog input of the input sequence;
generating in the analog processing domain, based on the third analog input and the second scaled analog residual error, a third analog output; and
quantizing the third analog output, resulting in a third quantized digital output.

4. The method of claim 2, wherein the third quantized digital output is accumulated with the first digital output and the second digital output, resulting in the accumulated digital output.

5. The method of claim 1, wherein each analog input and each scaled analog residual error is represented in the analog processing domain as a voltage change on an output line.

6. The method of claim 5, wherein each analog input is received on an input line capacitively coupled to the output line and each scaled analog residual error is stored in an analog data store capacitively coupled to the output line.

7. The method of claim 6, wherein the first scaled analog residual error is stored in the analog data store as a first pre-charge voltage on a first storage line of the analog data store captured from the output line prior to receiving the first analog input, and a first scaled residual voltage captured from the output line after scaling the first residual analog error, the scaled analog residual error being passed to the output line by switching an output of the analog data store from the pre-charge voltage to the scaled analog residual voltage.

8. The method of claim 7, wherein the first analog output is quantized using an inverter having an input coupled to the outline line, and the first pre-charge voltage is generated by coupling the input of the inverter to an output of the inverter.

9. The method of claim 1, wherein the first analog input is one of multiple first analog inputs received in parallel on respective input lines, the first analog output generated based on the multiple first analog inputs; and
wherein the second analog input is one of multiple second analog inputs received in parallel on the respective input lines, the second analog output generated based on the multiple second analog inputs.

10. The method of claim 3, wherein the third analog input is one of multiple third analog inputs received in parallel on the respective input lines, the third analog output generated based on the multiple third analog inputs.

11. The method of claim 9, comprising:
applying respective stored weights to the multiple first analog inputs on the respective input lines, the first analog output dependent on the weighted multiple first analog inputs; and
applying the respective stored weights to the multiple second analog inputs received on the respective input lines, the second analog output dependent on the weighted multiple second analog inputs.

12. The method of claim 11, wherein the respective input lines are coupled to the output line via respective input capacitors, wherein each analog input is represented in the analog processing domain as a voltage change.

13. The method of claim 12, wherein each analog input comprises a pair of mutually inverted zero or non-zero voltage deltas, and applying the stored weight comprises:
selecting, based on the stored weight, one of the pair of mutually inverted zero or non-zero voltage deltas, or
selecting, based on the stored weight, one of:
a zero voltage delta, or
one of the pair of mutually inverted zero or non-zero voltage deltas.

14. The method of claim 1, wherein the first analog input is quantized based on a quantization threshold, and the first quantized digital output comprises a first threshold count, wherein quantizing the first analog input in the analog processing domain comprises:
subtracting from the first analog input the quantization threshold, and determining whether the result is positive or negative, wherein if the result is positive, the first threshold count is incremented, and wherein if the result is negative, the first threshold count is not changed, and the quantization threshold is added to the result to restore the first analog input value; or
adding to the first analog input the quantization threshold, and determining whether the result is positive or negative, wherein if the result is negative, the first threshold count is decremented, and if the result is negative, the first threshold count is not changed and the quantization threshold is subtracted from the result to restore the first analog input value.

15. The method of claim 14, wherein quantizing the first analog input comprises both the subtracting and the adding operations.

16. The method of claim 3, wherein scaling the first analog residual error comprises decoupling an analog feedback path on which the first analog residual error is stored from a portion of the output line.

17. The method of claim 7, wherein a residual voltage remaining on the output line is captured in the analog data store wherein the first scaled analog residual error is generated on the output line by switching the output of the analog data store to the residual voltage when the analog feedback path is decoupled from said portion of the output line.

18. The method of claim 16, wherein said portion of the output line includes an output capacitor.

19. An analog computer comprising:
circuitry configured to implement a method, the method comprising:
receiving in an analog processing domain a first analog input of the sequence;
generating in the analog processing domain, based on the first analog input, a first analog output;
quantizing the first analog output, resulting in:
(i) a first quantized digital output, and
(ii) a first analog residual error;
scaling in the analog processing domain the first analog residual error, resulting in a first analog scaled residual error;
receiving in the analog processing domain a second analog input of the input sequence;
generating in the analog processing domain, based on the second analog input and the first scaled analog residual error, a second analog output; and
quantizing the second analog output, resulting in a second quantized digital output.

20. A device comprising:
an output line;
an input line coupled to the output line;
an analog data store coupled to the output line;
an analog-to-digital converter (ADC) configured to quantize an earlier analog output value on the output line, the earlier analog output value dependent on an earlier analog input value received on the input line, resulting in an earlier quantized digital output, the ADC coupled to the analog data store so as to cause an analog residual error arising from quantizing the earlier analog output value to be stored in the analog data store; and
an error scaling circuit configured to scale the analog residual error, thereby causing a scaled analog residual error to be stored in the analog data store, wherein the ADC is configured to quantize a later analog output value on the output line, resulting in a later quantized digital output, the later analog output value dependent on the scaled analog residual error and a later analog input value received on the input line.
